(19) United States
(12) Patent Application Publication
(10) Pub. No.: US 2025/0329675 A1
(43) Pub. Date: Oct. 23, 2025

(54) SEMICONDUCTOR DEVICE AND METHODS OF FORMATION

(71) Applicant: Taiwan Semiconductor Manufacturing Company, Ltd., Hsinchu (TW)

(72) Inventors: Yi-Shan HSIEH, Hsinchu City (TW); Jo-Lin LAN, Kaohsiung City (TW); Chi-Feng LIN, Hsinchu City (TW); Hsiang-Ku SHEN, Hsinchu City (TW); Chen-Chiu HUANG, Taichung City (TW); Dian-Hau CHEN, Hsinchu (TW)

(21) Appl. No.: 18/643,423

(22) Filed: Apr. 23, 2024

(51) Int. Cl. H01L 23/00; H01L 23/538; H01L 25/065

(52) U.S. Cl. CPC H01L 24/08; H01L 23/5383; H01L 23/5384; H01L 24/03; H01L 24/94; H01L 25/0657; H01L 2224/03622; H01L 2224/08111; H01L 2224/08146; H01L 2224/94; H01L 2225/06513; H01L 2225/06544; H01L 2924/30101

(57) ABSTRACT

A semiconductor die includes top conductive structures of different sizes, and bonding vias are formed only on the larger top conductive structures. Forming the bonding vias on the larger top conductive structures results in lesser vertical dimensions for the bonding vias of the semiconductor die, which reduces the amount of narrowing that occurs in the width of the bonding vias. This results in a greater amount of surface area contact between the bottom of the bonding vias and the underlying top conductive structures, which enables a low contact resistance to be achieved between the bonding vias and the underlying top conductive structures.

### BACKGROUND

Bonding in the semiconductor industry is a technique that may be used to form stacked semiconductor devices and three-dimensional integrated circuits. Some examples of bonding include wafer-to-wafer bonding, die-to-wafer bonding, and die-to-die bonding, among other examples.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example of a semiconductor device described herein.

FIGS. 2A-2C are diagrams of an example of a semiconductor device described herein.

FIGS. 3A-3O are diagrams of an example implementation of forming a semiconductor die described herein.

FIGS. 4A and 4B are diagrams of an example implementation of forming a semiconductor device described herein.

FIG. 5 is a diagram of an example of a semiconductor device described herein.

FIG. 6 is a diagram of an example of a semiconductor device described herein.

FIG. 7 is a diagram of an example of a semiconductor device described herein.

FIG. 8 is a flowchart of an example process associated with forming a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Bonding pads and bonding vias are widely used for bonding semiconductor dies to form three-dimensional semiconductor devices. Bonding of a first semiconductor die and a second semiconductor die may be achieved by bonding the bonding pads on the first semiconductor die with the bonding pads on the second semiconductor die to form metal-to-metal bonds, and by bonding dielectric layers surrounding the bonding pads on the first semiconductor die and on the second semiconductor die to form dielectric-to-dielectric bonds. The bonding vias of a semiconductor die may be physically coupled with underlying metallization layers that are used for routing signals and/or power within the semiconductor die and/or between the semiconductor die and another semiconductor die to which the semiconductor die is bonded.

Some semiconductor dies have differing sizes of top conductive structures in the same metallization layer for different functions (e.g., larger top conductive structures for routing higher power signals and smaller top conductive structures for routing lower power signals). Having different sized top conductive structures in the same metallization layer under the bonding vias of a semiconductor die may result in different vertical dimensions (e.g., different lengths) for the bonding vias of the semiconductor die. Since the bonding vias are formed in recesses in a dielectric layer, bonding vias that are formed over shorter top conductive structures end up being longer in the vertical dimension in the semiconductor die than bonding vias that are formed over taller top conductive structures.

The longer the bonding vias are in the semiconductor device, the more likely (and more substantially) that the bonding vias will suffer from increased contact resistance. The increased contact resistance results from the narrowing of a width of a bonding via from the top of the bonding via to the bottom of the bonding via. The narrowing occurs because of the bonding via being formed in a recess that is etched in a dielectric layer and conforming to the profile of the recess. The further into a dielectric layer the recess is etched into the dielectric layer, the greater the narrowing that occurs from the top of the recess to the bottom of the recess. This occurs because of an etchant that is used to form the recess being in contact for a longer time duration with the dielectric layer at the top of the recess than at the bottom of the recess. This results in the recess having a tapered profile in which the top width of the recess is greater than the bottom width of the recess, resulting in the narrowing of the width of a bonding via that is formed in the recess. The lesser width at the bottom of the bonding via results in less surface area contact between the bonding via and the underlying top conductive structure, which results in increased contact resistance between the bonding via and the underlying top conductive structure.

In some implementations described herein, a semiconductor die includes top conductive structures of different sizes, and bonding vias and associated bonding pads are formed only on the larger top conductive structures. Forming the bonding vias on the larger top conductive structures results in smaller vertical dimensions (e.g., shorter lengths) for the bonding vias of the semiconductor die, which reduces the amount of narrowing that occurs in the width of the bonding vias. In particular, the larger top conductive structures in the semiconductor die may be taller than the smaller top conductive structures in the semiconductor die, and therefore the vertical distance that the bonding vias span in the semiconductor die is reduced, which reduces the amount of narrowing that occurs in the width of the bonding vias. This results in a greater amount of surface area contact between the bottom of the bonding vias and the underlying top conductive structures (e.g., the larger top conductive structures), which enables a low contact resistance to be achieved between the bonding vias and the underlying top conductive structures.

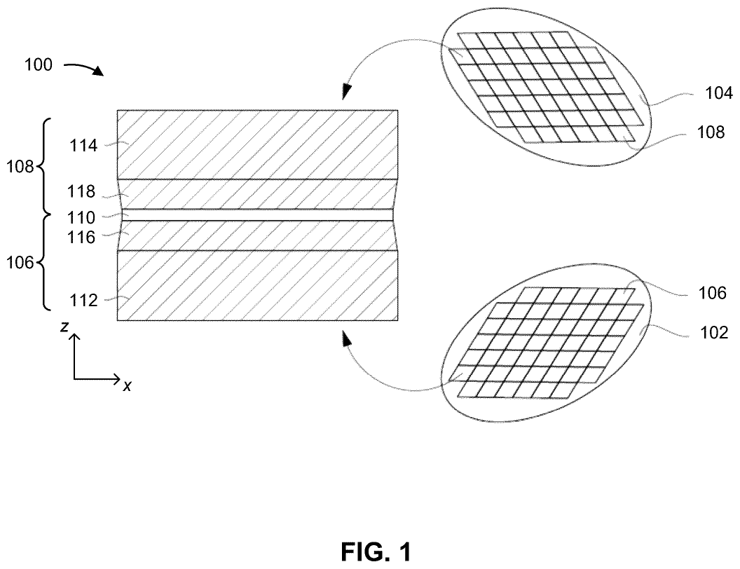

FIG. 1 is a diagram of an example of a semiconductor device 100 described herein. As shown in FIG. 1, the semiconductor device 100 is formed by bonding a semiconductor wafer 102 and a semiconductor wafer 104. For example, a bonding tool may be used to perform a bonding operation to bond the semiconductor wafer 102 and the semiconductor wafer 104 by forming metal-to-metal bonds and/or dielectric-to-dielectric bonds between the semiconductor wafer 102 and the semiconductor wafer 104. In the bonding operation, semiconductor dies 106 on the semiconductor wafer 102 are bonded with associated semiconductor dies 108 on the semiconductor wafer 104 to form semiconductor devices 100 (e.g., stacked semiconductor devices). The semiconductor devices 100 are then diced and packaged. Other processing steps may be performed to form the semiconductor devices 100.

A semiconductor die 106 and the semiconductor die 108 may be bonded at a bonding interface 110. The semiconductor device 100 includes a stacked semiconductor device in that the semiconductor die 106 and the semiconductor die 108 are stacked or vertically arranged in a z-direction in the semiconductor device 100. The semiconductor die 106 may include a system on chip (SoC) die, such as a logic die, a central processing unit (CPU) die, a graphics processing unit (GPU) die, a digital signal processing (DSP) die, an application specific integrated circuit (ASIC) die, and/or another type of SoC die. Additionally and/or alternatively, the semiconductor die 106 may include a memory die, an input/output (I/O) die, a pixel sensor die, and/or another type of semiconductor die. A memory die may include a static random access memory (SRAM) die, a dynamic random access memory (DRAM) die, a NAND die, a high bandwidth memory (HBM) die, and/or another type of memory die. The semiconductor die 108 may include the same type of semiconductor die as the semiconductor die 106, or may include a different type of semiconductor die.

As further shown in FIG. 1, the semiconductor die 106 may include a device layer 112, and the semiconductor die 108 may include a device layer 114. The device layers 112 and 114 may include the integrated circuit devices of the semiconductor dies 106 and 108, respectively. The integrated circuit devices may include transistors, pixel sensors, capacitors, resistors, other active circuit devices and/or other passive circuit devices, among other examples.

The semiconductor die 106 may include an interconnect layer 116 above the device layer 112. The semiconductor die 108 may include an interconnect layer 118 below the device layer 114. The interconnect layers 116 and 118 may each include conductive structures that interconnect the integrated circuit devices of the device layers 112 and 114, respectively. Additionally and/or alternatively, the interconnect layers 116 and 118 may each include conductive structures that electrically connect the semiconductor dies 106 and 108.

The bonding interface 110 may be located between the interconnect layers 116 and 118 and may include portions of each of the interconnect layers 116 and 118. The bonding interface 110 may include conductive structures of the interconnect layers 116 and 118 that are bonded together by metal-to-metal bonds, and/or dielectric layers of the interconnect layers 116 and 118 that are bonded together by dielectric-to-dielectric bonds.

As indicated above, FIG. 1 is provided as an example. Other examples may differ from what is described with regard to FIG. 1.

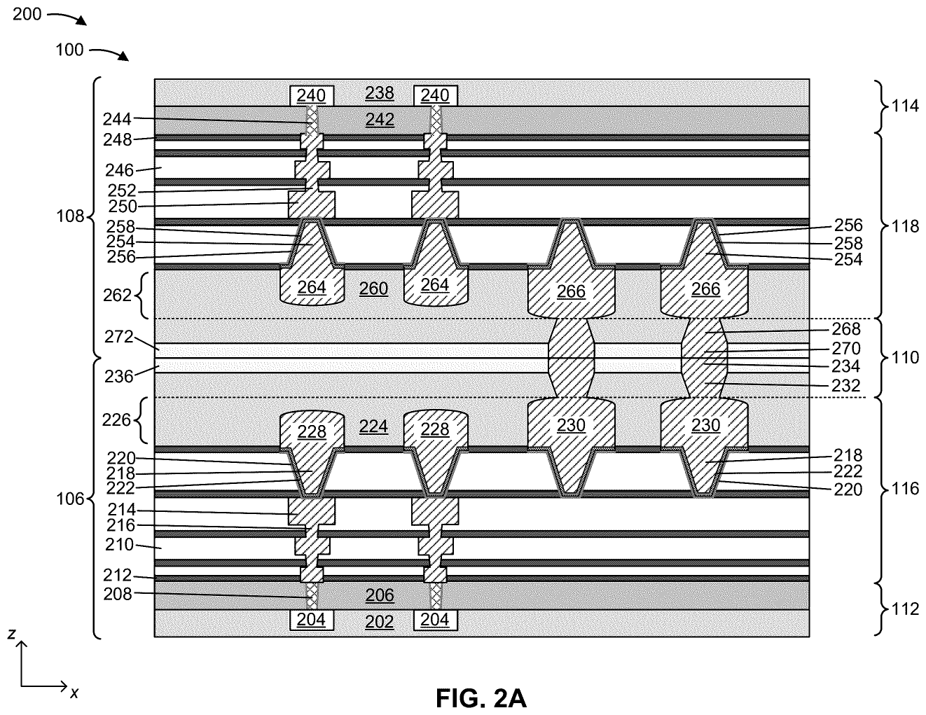

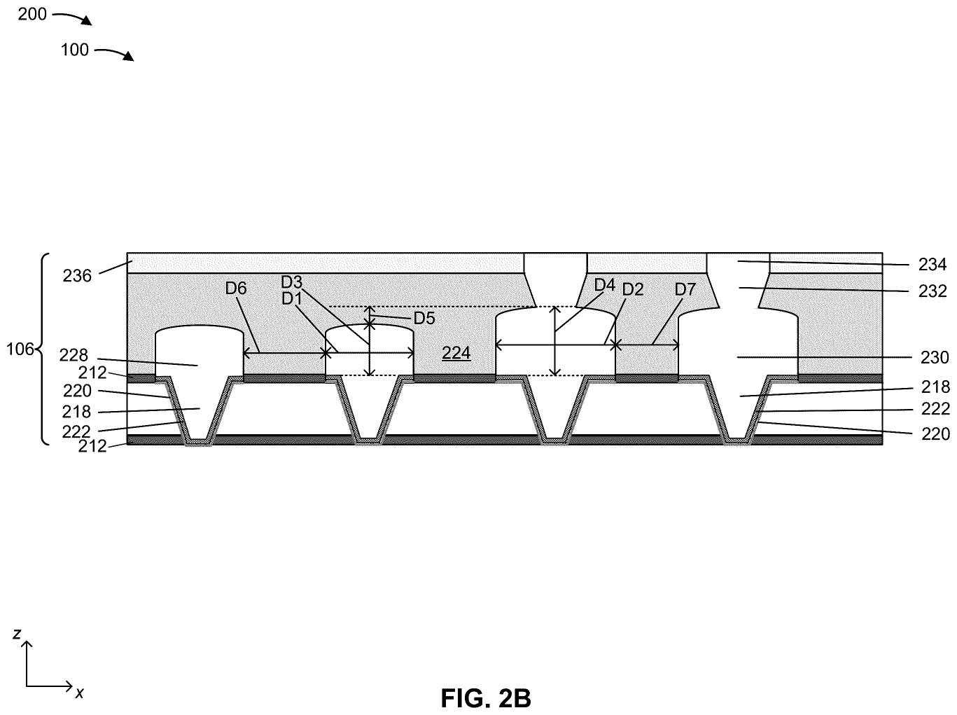

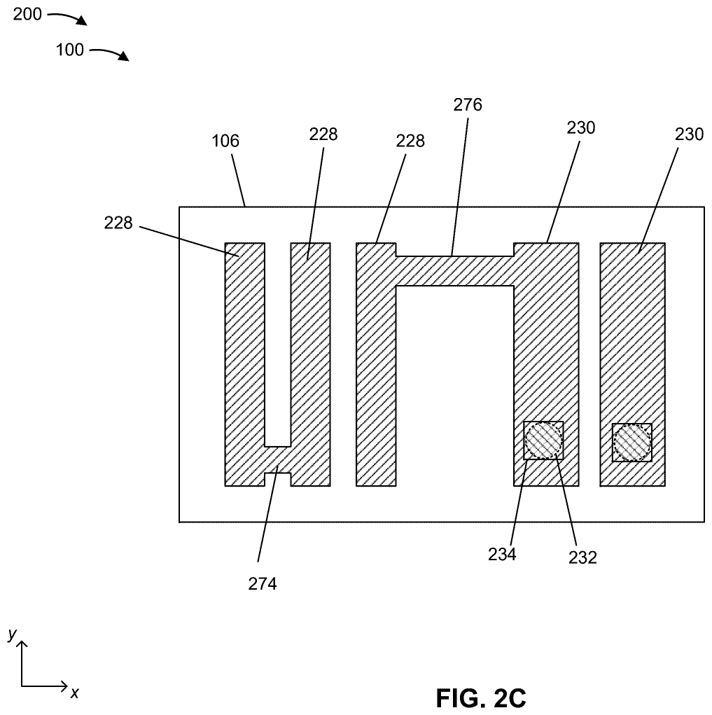

FIGS. 2A-2C are diagrams of an example 200 of a semiconductor device 100 described herein. FIG. 2A illustrates a cross-sectional view of the semiconductor device 100 in which the details of the semiconductor dies 106 and 108 are shown. In particular, FIG. 2A further illustrates details of the device layers 112 and 114, details of the interconnect structures 116 and 118, and details of the bonding interface 110.

As shown in FIG. 2A, the device layer 112 of the semiconductor die 106 includes a substrate 202. The substrate 202 may correspond to a portion of the semiconductor wafer 102 on which the semiconductor die 106 is formed. The substrate 202 may include a silicon (Si) substrate, a substrate formed of a material including silicon, a III-V compound semiconductor material substrate such as gallium arsenide (GaAs), a silicon on insulator (SOI) substrate, or another type of semiconductor substrate. The substrate 202 may extend in an x-direction and/or in a y-direction in the semiconductor die 106.

The device layer 112 of the semiconductor die 106 includes integrated circuit devices 204 in the substrate 202 and/or on the substrate 202. The integrated circuit devices 204 include transistors (e.g., planar transistors, fin field effect transistors (finFETs), gate all around (GAA) transistors), pixel sensors, capacitors, resistors, inductors, photodetectors, transceivers, transmitters, receives, optical circuits, and/or other types of passive and/or active integrated circuit devices.

A dielectric layer 206 of the device layer 112 is included over the substrate 202. The dielectric layer 206 includes an interlayer dielectric (ILD) layer, an etch stop layer (ESL), and/or another type of dielectric layer. In some implementations, portions of the integrated circuit devices 204 are included in the dielectric layer 206. For example, gate structures of the transistors of the integrated circuit devices 204 may be included in the dielectric layer 206, and source/drain regions and channel regions of the transistors may be included in the substrate 202. Additionally and/or alternatively, contacts 208 for the integrated circuit devices 204 may be included in the dielectric layer 206. The contacts 208 may include plugs, vias, pads, and/or other types of electrical contacts. In some implementations, an integrated circuit device 204 includes one or more source/drain contacts and one or more gate contacts. The contacts 208 may include one or more electrically conductive materials such as tungsten (W), cobalt (Co), ruthenium (Ru), and/or titanium (Ti), among other examples. In some implementations, one or more liner layers are included between the contacts 208 and the dielectric layer 206 to promote adhesion between the contacts 208 and the dielectric layer 206. The liner layers may include tantalum nitride (TaN), titanium nitride (TiN), and/or another suitable liner layer.

The dielectric layer 206 includes dielectric material(s) that enable various portions of the substrate 202 and/or the integrated circuit devices 204 to be selectively etched or protected from etching, and/or to electrically isolate the integrated circuit devices 204 in the device layer 112. The dielectric layer 206 includes a silicon nitride (SiₓN_{y}), an oxide (e.g., a silicon oxide (SiOₓ) and/or another oxide material), and/or another type of dielectric material. The dielectric layer 206 may extend in the x-direction and/or in the y-direction in the semiconductor die 106.

An interconnect layer 116 of the semiconductor die 106 is included above the substrate 202 and above the integrated circuit devices 204. In some implementations, one or more integrated circuit devices 204 are included in the interconnect layer 116 (e.g., a backend memory device, a backend resistor, a backend capacitor, a radio frequency (RF) switch, an optical modulator, a waveguide). The interconnect layer 116 includes a plurality of dielectric layers that are arranged in a direction (e.g., the z-direction) that is approximately perpendicular to the substrate 202. The dielectric layers may include backend dielectric layers 210 (e.g., ILD layers, intermetal dielectric (IMD) layers) and ESLs 212 that are arranged in an alternating manner in the z-direction. The backend dielectric layers 210 may each include an oxide (e.g., a silicon oxide (SiOₓ) and/or another oxide material), an undoped silicate glass (USG), a boron-containing silicate glass (BSG), a fluorine-containing silicate glass (FSG), and/or another suitable dielectric material. In some implementations, a backend dielectric layer 210 includes an extreme low dielectric constant (ELK) dielectric material having a dielectric constant that is less than approximately 2.5. The ESLs 212 may each include a silicon nitride (SiₓN_{y}), silicon carbide (SiC), silicon oxynitride (SiON), and/or another suitable dielectric material. In some implementations, a backend dielectric layer 210 and an ESL 212 include different dielectric materials to provide etch selectivity to enable various structures to be formed in the interconnect layer 116. The backend dielectric layers 210 and the ESLs 212 may each extend in the x-direction and/or in the y-direction in the semiconductor die 106.

The interconnect layer 116 includes a plurality of conductive interconnects in the backend dielectric layers 210 and in the ESLs 212. The conductive interconnects are electrically coupled and/or physically coupled with one or more of the integrated circuit devices 204 in the device layer 112 and/or in the interconnect layer 116. The conductive interconnects correspond to circuit routing that enables signals and/or power to be provided to and/or from the integrated circuit devices 204. The conductive interconnects may include a combination of conductive structures 214 (e.g., trenches, conductive lines) that are interconnected by interconnect structures 216 (e.g., vias). The conductive structures 214 and interconnect structures 216 may each include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials.

As shown in FIG. 2A, the conductive interconnects of the interconnect layer 116 may be arranged in in a vertical manner (e.g., in the z-direction) to facilitate electrical signals and/or power to be routed between the device layer 112, between integrated circuit devices 204 through the interconnect layer 116, and/or between the integrated circuit devices 204 and the semiconductor die 108. The conductive interconnects may be arranged in alternating layers of metallization layers (referred to as “M”-layers) and via layers (referred to as “V”-layers). Each metallization layer may include one or more conductive structures 214 laterally arranged in an x-y plane in the interconnect layer 116, and each via layer may include one or more interconnect structures 216 laterally arranged in an x-y plane in the interconnect layer 116. As an example, a metal-0 (M0) layer (including one or more conductive structures 214) may be located at the bottom of the interconnect layer 116 and may be coupled with the contacts 208 of the integrated circuit devices 204 in the device layer 112, a via-1 (V1) layer (including one or more interconnect structures 216) may be located above and coupled with the M0 layer in the interconnect layer 116, a metal-1 layer (M1) layer may be located above and coupled with the V1 layer in the interconnect structure 216, a via-2 (V2) layer may be located above and coupled with the M1 layer in the interconnect layer 116, a metal-2 layer (M2) layer may be located above and electrically coupled with the V2 layer in the interconnect layer 116, and so on. In some implementations, the interconnect layer 116 includes nine (9) stacked metallization layers (e.g., M0-M8). In some implementations, the interconnect layer 116 includes another quantity of stacked metallization layers.

The interconnect layer 116 includes a top via layer and a top metallization layer. The top via layer is the top-most via layer in the interconnect layer 116 and is the via layer that is closest to the bonding interface 110. Similarly, the top metallization layer is the top-most metallization layer in the interconnect layer 116 and is the metallization layer that is closest to the bonding interface 110. The top via layer includes top interconnect structures 218 (top vias) in a backend dielectric layer 210 and/or in an ESL 212. The top interconnect structures 218 may include copper (Cu) structures and/or another type of metal structures. Barrier layers 220 may be included between the top interconnect structures 218 and the backend dielectric layer 210 and/or the ESL 212, and may be included to prevent or minimize diffusion of material (e.g., copper atoms) of the top interconnect structures 218 into the surrounding backend dielectric layers 210 and/or the surrounding ESLs 212. Examples of barrier layers 220 include tantalum nitride (TaN) and/or titanium nitride (TiN), among other examples. In some implementations, adhesion layers 222 are included between the top interconnect structures 218 and the barrier layers 220. The adhesion layers 222 may include material(s) that promote adhesion between the top interconnect structures 218 and the surrounding backend dielectric layers 210 and/or the surrounding ESLs 212. In some implementations, the adhesion layers 222 include copper seed layers. In some implementations, the adhesion layers 222 include another type of adhesion material that promotes adhesion of copper to dielectric materials.

A backend dielectric layer 224 may be included over the backend dielectric layers 210 and the ESLs 212 of the interconnect layer 116. The backend dielectric layer 224 may be partially included in the bonding interface 110 between the semiconductor die 106 and the semiconductor die 108. The backend dielectric layer 224 may include one or more ELK dielectric materials such as carbon doped silicon oxide (C—SiOₓ), amorphous fluorinated carbon (a-CₓF_{y}), parylene, bis-benzocyclobutenes (BCB), polytetrafluoroethylene (PTFE), and/or a silicon oxycarbide (SiOC) polymer. In some implementations, the ELK dielectric material(s) for the backend dielectric layer 224 include porous hydrogen silsesquioxane (HSQ), porous methyl silsesquioxane (MSQ), porous polyarylether (PAE), and/or porous silicon oxide (SiOₓ), among other examples. Additionally and/or alternatively, the backend dielectric layer 224 may include silicon oxide (SiOₓ such as SiO₂), USG, BSG, and/or another suitable dielectric material.

A top metallization layer 226 is included in the backend dielectric layer 224. The top metallization layer 226 is above and electrically coupled with the top via layer in the interconnect layer 116. The top metallization layer 226 includes a plurality of types of top conductive structures, including top conductive structures 228 and top conductive structures 230. The top conductive structures 228 are physically smaller (e.g., shorter and narrower) than the top conductive structures 230 and are only used for routing of signals and/or power in the semiconductor die 106 (e.g., intra-die routing). In other words, the top conductive structures 228 are not coupled with bonding structures of the semiconductor die 106 in the bonding interface 110. As a result, the entireties of the top surfaces of the top conductive structures 228 are in direct physical contact with, and are covered by, the backend dielectric layer 224.

The top conductive structures 230 are physically larger (e.g., taller and wider) than the top conductive structures 228 and are used for supporting the bonding structures of the semiconductor die 106, in addition to routing of signals and/or power between the semiconductor die 106 and the semiconductor die 108 (e.g., inter-die routing). Each of the top conductive structures 230 is coupled with a bonding via 232 in the backend dielectric layer 224. Thus, at least a portion of each of the top surfaces of the top conductive structures 230 are in direct physical contact with an associated bonding via 232 that is located in the bonding interface 110. In some implementations, another portion of each of the top surfaces (e.g., a portion surrounding the portion that is in direct physical contact with a bonding via 232) of the top conductive structures 230 is in direct physical contact with the backend dielectric layer 224.

In some implementations, signals and/or power may be routed between top conductive structures 228. In some implementations, signals and/or power may be routed between top conductive structures 230. In some implementations, signals and/or power may be directly routed through a direct connection between a top conductive structure 228 and a top conductive structure 230 in the metallization layer 226. In some implementations, signals and/or power may be indirectly routed between a top conductive structure 228 and a top conductive structure 230 through one or more top conductive structures 214, through one or more interconnect structures 216, and/or through one or more top interconnect structures 218.

The bonding vias 232 each include a via structure that is elongated in the z-direction. The bonding vias 232 may each be physically coupled and electrically coupled with an associated top conductive structure 230. Coupling the bonding vias 232 with the top conductive structures 230 (e.g., as opposed to the top conductive structures 228) results in shorter bonding vias 232 (e.g., shorter in the z-direction), which reduces contact resistance between the bonding vias 232 and the top metallization layer 226.

Bonding pads 234 are included on the bonding vias 232 such that the bonding pads 234 and the bonding vias 232 are physically coupled and electrically coupled. The bonding pads 234 may each have a smaller z-direction dimension than an x-direction dimension and/or a y-direction dimension. The bonding vias 232 and the bonding pads 234 may each include tungsten (W), cobalt (Co), ruthenium (Ru), titanium (Ti), aluminum (Al), copper (Cu), gold (Au), and/or a combination thereof, among other examples of electrically conductive metals.

The bonding pads 234 are included in a bonding dielectric layer 236 that is above and/or on the backend dielectric layer 224. The bonding dielectric layer 236 may be included in the bonding interface 110 and may include a silicon oxynitride (SiON) and/or another suitable bonding dielectric material.

As further shown in FIG. 2A, the semiconductor die 108 may include a similar combination and/or arrangement of structures and/or layers as the semiconductor die 106. For example, the semiconductor die 108 may include a combination of a substrate 238, integrated circuit devices 240, a dielectric layer 242, and contacts 244 in the device layer 114 of the semiconductor die 108, similar to the device layer 112 of the semiconductor die 106. As another example, the semiconductor die 108 may include a combination of backend dielectric layers 246, ESLs 248, conductive structures 250, and interconnect structures 252 in the interconnect layer 118 of the semiconductor die 108, similar to the interconnect layer 116 of the semiconductor die 106. These layers and/or structures may have a reversed z-direction arrangement relative to the semiconductor die 106, which enables the semiconductor die 106 and the semiconductor die 108 to be bonded at the bonding interface 110 such that the interconnect layer 116 and the interconnect layer 118 are facing each other.

Moreover, the interconnect layer 118 includes a top via layer and a top metallization layer. The top via layer is the top-most via layer in the interconnect layer 118 and is the via layer that is closest to the bonding interface 110. Similarly, the top metallization layer is the top-most metallization layer in the interconnect layer 118 and is the metallization layer that is closest to the bonding interface 110. The top via layer includes top interconnect structures 254 (top vias) in a backend dielectric layer 246 and/or in an ESL 248. The top interconnect structures 254 may include copper (Cu) structures and/or another type of metal structures. Barrier layers 256 and/or adhesion layers 258 may be included between the top interconnect structures 254 and the backend dielectric layer 246 and/or the ESL 248, and/or are included between the top interconnect structures 254 and the barrier layers 256.

A backend dielectric layer 260 may be included over (or under) the backend dielectric layers 246 and the ESLs 248 of the interconnect layer 118. The backend dielectric layer 260 may be partially included in the bonding interface 110 between the semiconductor die 106 and the semiconductor die 108. The backend dielectric layer 260 may include similar material(s) as the backend dielectric layer 224, and/or may include different material(s).

A top metallization layer 262 is included in the backend dielectric layer 260. The top metallization layer 262 is below and electrically coupled with the top via layer in the interconnect layer 118. The top metallization layer 262 includes a plurality of types of top conductive structures, including top conductive structures 264 and top conductive structures 266. The top conductive structures 264 are physically smaller (e.g., shorter and narrower) than the top conductive structures 266 and are only used for routing of signals and/or power in the semiconductor die 108 (e.g., intra-die routing). In other words, the top conductive structures 264 are not coupled with bonding structures of the semiconductor die 108 in the bonding interface 110. As a result, the entireties of the top surfaces of the top conductive structures 264 are in direct physical contact with, and are covered by, the backend dielectric layer 260.

The top conductive structures 266 are physically larger (e.g., taller and wider) than the top conductive structures 264 and are used for supporting the bonding structures of the semiconductor die 108, in addition to routing of signals and/or power between the semiconductor die 106 and the semiconductor die 108 (e.g., inter-die routing). Each of the top conductive structures 266 is coupled with a bonding via 268 in the backend dielectric layer 260. Thus, at least a portion of each of the top surfaces of the top conductive structures 266 are in direct physical contact with an associated bonding via 268 that is located in the bonding interface 110. In some implementations, another portion of each of the top surfaces (e.g., a portion surrounding the portion that is in direct physical contact with a bonding via 268) of the top conductive structures 266 is in direct physical contact with the dielectric layer 260.

In some implementations, signals and/or power may be routed between top conductive structures 264. In some implementations, signals and/or power may be routed between top conductive structures 266. In some implementations, signals and/or power may be directly routed through a direct connection between a top conductive structure 264 and a top conductive structure 266 in the metallization layer 262. In some implementations, signals and/or power may be indirectly routed between a top conductive structure 264 and a top conductive structure 266 through one or more top conductive structures 250, through one or more interconnect structures 252, and/or through one or more top interconnect structures 254.

The bonding vias 268 each include a via structure that is elongated in the z-direction. The bonding vias 268 may each be physically coupled and electrically coupled with an associated top conductive structure 266. Coupling the bonding vias 268 with the top conductive structures 266 (e.g., as opposed to the top conductive structures 264) results in shorter bonding vias 268 (e.g., shorter in the z-direction), which reduces contact resistance between the bonding vias 268 and the top metallization layer 262.

Bonding pads 270 are included on the bonding vias 268 such that the bonding pads 270 and the bonding vias 268 are physically coupled and electrically coupled. The bonding pads 270 may each have a smaller z-direction dimension than an x-direction dimension and/or a y-direction dimension. The bonding vias 268 and the bonding pads 270 may each include tungsten (W), cobalt (Co), ruthenium (Ru), titanium (Ti), aluminum (Al), copper (Cu), gold (Au), and/or a combination thereof, among other examples of electrically conductive metals.

The bonding pads 270 are included in a bonding dielectric layer 272 that is on and/or under the backend dielectric layer 260. The bonding dielectric layer 272 may be included in the bonding interface 110 and may include a silicon oxynitride (SiON) and/or another suitable bonding dielectric material.

At the bonding interface 110, the bonding pads 234 of the semiconductor die 106 and the bonding pads 270 of the semiconductor die 108 are directly bonded by metal-to-metal bonds. Moreover, the bonding dielectric layer 236 of the semiconductor die 106 and the bonding dielectric layer 272 of the semiconductor die 108 are directly bonded by dielectric-to-dielectric bonds. The bonding vias 232 and 268, and the bonding pads 234 and 270 are located between the top conductive structures 230 and the top conductive structures 266. For example, a bonding via 232, a bonding pad 234, a bonding pad 270, and a bonding via 268 are located between a top conductive structure 230 and a top conductive structure 266.

As indicated above, the top conductive structures 228 and 264 are separated from bonding pads or bonding vias. Thus, portions of the backend dielectric layer 224, portions of the bonding dielectric layer 236, portions of the backend dielectric layer 260, and portions of the bonding dielectric layer 272 are included directly between the top conductive structures 228 and 264. For example, a portion of the bonding dielectric layer 236, a portion of the backend dielectric layer 260, and a portion of the bonding dielectric layer 272 are each included directly between a top conductive structure 228 and a top conductive structure 264 (e.g., without intervening bonding pads or bonding vias).

FIG. 2B illustrates one or more example dimensions of the semiconductor die 106. The example dimensions of the semiconductor die 106 illustrated and described in connection with FIG. 2B may additionally apply and/or alternatively apply to the semiconductor die 108.

As shown in FIG. 2B, an example dimension D1 includes a cross-sectional width (e.g., an x-direction width, a y-direction width) of a top conductive structure 228. The dimension D1 may additionally and/or alternatively include a cross-sectional width of a top conductive structure 264. In some implementations, the dimension D1 is included in a range of approximately 1.2 microns to approximately 3 microns. If the cross-sectional width of the top conductive structures 228 is too large (e.g., greater than approximately 3 microns), insufficient spacing may be provided between adjacent top conductive structures 228, resulting in increased signal noise and/or increased parasitic capacitance, among other examples. If the cross-sectional width of the top conductive structures 228 is too small (e.g., less than approximately 1.2 microns), the resulting height of the top conductive structures 228 may be too small and result in increased resistance for the top conductive structures 228. If the cross-sectional width of the top conductive structures 228 is included in the range of approximately 1.2 microns to approximately 3 microns, sufficient spacing may be achieved for the top conductive structures 228 while achieving a sufficient height for the top conductive structures 228 to achieve a low resistance for the top conductive structures 228. However, other ranges and other values for the dimension D1 are within the scope of the present disclosure. In some implementations, the dimension D1 is included in a range of approximately 1 micron to approximately 3.5 microns.

Another example dimension D2 includes a cross-sectional width (e.g., an x-direction width, a y-direction width) of a top conductive structure 230. The dimension D2 may additionally and/or alternatively include a cross-sectional width of a top conductive structure 266. In some implementations, the dimension D2 is included in a range of approximately 3 microns to approximately 32 microns. If the cross-sectional width of the top conductive structures 230 is too large (e.g., greater than approximately 32 microns), insufficient spacing may be provided between adjacent top conductive structures 230, resulting in increased signal noise and/or increased parasitic capacitance, among other examples. If the cross-sectional width of the top conductive structures 230 is too small (e.g., less than approximately 3 microns), the resulting height of the top conductive structures 230 may be too small, which may result in increased z-direction length for the bonding vias 232. This may result in increased contact resistance for the bonding vias 232. If the cross-sectional width of the top conductive structures 230 is included in the range of approximately 3 microns to approximately 32 microns, sufficient spacing may be achieved for the top conductive structures 230 while achieving a sufficient height for the top conductive structures 230 to achieve a low contact resistance for the bonding vias 232. However, other ranges and other values for the dimension D2 are within the scope of the present disclosure. In some implementations, the dimension D2 is included in a range of approximately 2.5 microns to approximately 37 microns.

As indicated above, the width of the top conductive structures 230 is greater than the width of the top conductive structures 228. Similarly, the width of the top conductive structures 266 is greater than the width of the top conductive structures 264. Accordingly, the dimension D2 is greater than the dimension D1. In some implementations, a ratio of the dimension D2 to the dimension D1 is included in a range of approximately 2.5:1 to approximately 10.66:1. However, other ranges for the ratio of the dimension D2 to the dimension D1 are within the scope of the present disclosure.

Another example dimension D3 includes a z-direction height (or thickness) of a top conductive structure 228. The z-direction height (or thickness) of a top conductive structure 228 is from a bottom of the top conductive structure 228 (which may be in line with the top of the ESL 212 at the top of the top interconnect structure 218 below of the top conductive structure 228) to a top of the top conductive structure 228 (the highest part of the curve of the top surface of the top conductive structure 228). In other words, the z-direction height (or thickness) of a top conductive structure 228 is from the start of the taper of the underlying top interconnect structure 218 to the top of the curvature of the top conductive structure 228. The dimension D3 may additionally and/or alternatively include a z-direction height (or thickness) of a top conductive structure 264. Another example dimension D4 includes a z-direction height (or thickness) of a top conductive structure 230. The dimension D4 may additionally and/or alternatively include a z-direction height (or thickness) of a top conductive structure 266. As indicated above, the height of the top conductive structures 230 is greater than the height of the top conductive structures 228. Similarly, the height of the top conductive structures 266 is greater than the height of the top conductive structures 264. Accordingly, the dimension D4 is greater than the dimension D3, resulting a height difference corresponding to a dimension D5 illustrated in FIG. 2B. In some implementations, the dimension D5 is included in a range of approximately 1.6 microns to approximately 2.4 microns. However, other ranges for the dimension D5 are within the scope of the present disclosure. The height difference between the top conductive structure 228 and the top conductive structure 230 results in the top surface of the top conductive structure 230 being located closer to the bonding dielectric layer 236 than the top surface of the top conductive structure 228. Similarly, the height difference between the top conductive structure 264 and the top conductive structure 266 results in the top surface of the top conductive structure 266 being located closer to the bonding dielectric layer 272 than the top surface of the top conductive structure 264.

Another example dimension D6 includes a distance (or spacing) between adjacent top conductive structures 228. The dimension D6 may additionally and/or alternatively include a distance (or spacing) between adjacent top conductive structures 264. Another example dimension D7 includes a distance (or spacing) between adjacent top conductive structures 230. The dimension D7 may additionally and/or alternatively include a distance (or spacing) between adjacent top conductive structures 266. The dimension D6 may be greater than the dimension D7 because of the lesser width of the top conductive structures 228. However, in some implementations the dimension D6 and the dimension D7 may be approximately equal, and in other implementations the dimension D7 may be greater than the dimension D6.

FIG. 2C illustrates a top view example of the semiconductor die 106 in an x-y plane. As shown in the top view example, two or more top conductive structures 228 may be electrically connected a connecting structure 274. The connecting structure 274 may be included in the metallization layer 226 and may enable signals and/or power to be routed between the two or more top conductive structures 228. Additionally and/or alternatively, a connecting structure 276 may be included between a top conductive structure 228 and a top conductive structure 230, which enables signals and/or power to be routed between the top conductive structure 228 and the top conductive structure 230. Moreover, the connecting structure 276 enables signals and/or power to be routed between the top conductive structure 228 and the semiconductor die 108 through the top conductive structure 230.

The top conductive structures 228 and the top conductive structures 230 may be arranged in the x-direction and may each extend in the y-direction in the semiconductor device 100. The connecting structure 274 and the connecting structure 276 may each extend in the x-direction in the semiconductor device 100.

As indicated above, FIGS. 2A-2C are provided as examples. Other examples may differ from what is described with regard to FIGS. 2A-2C.

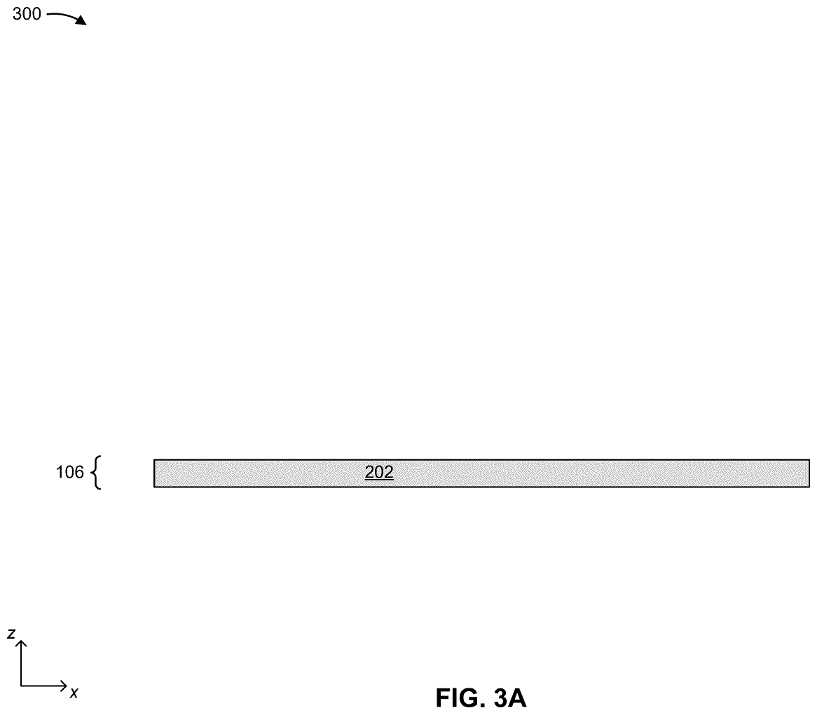

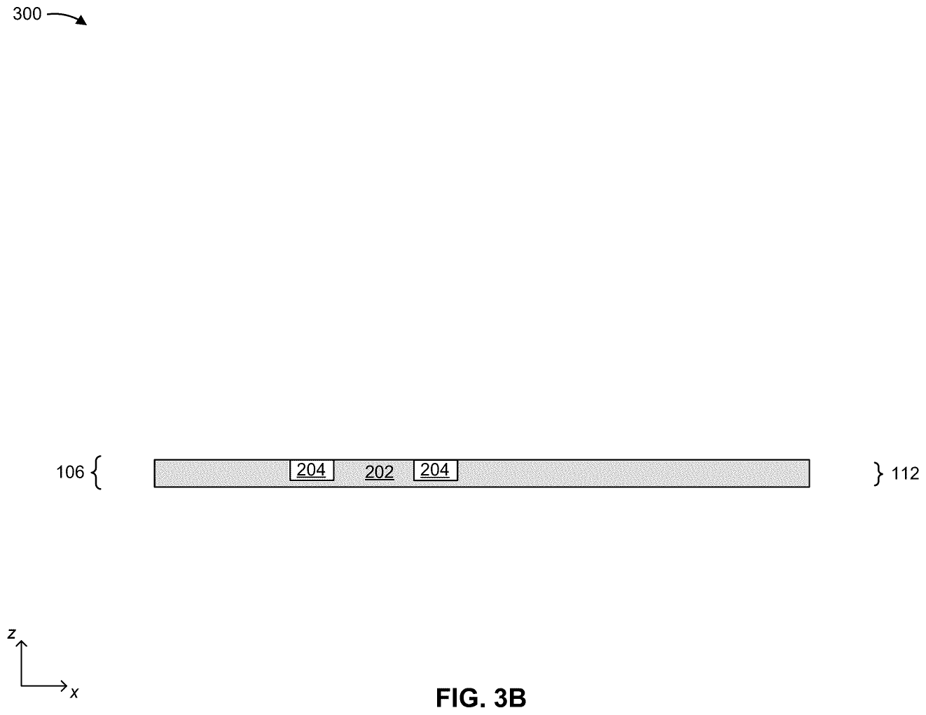

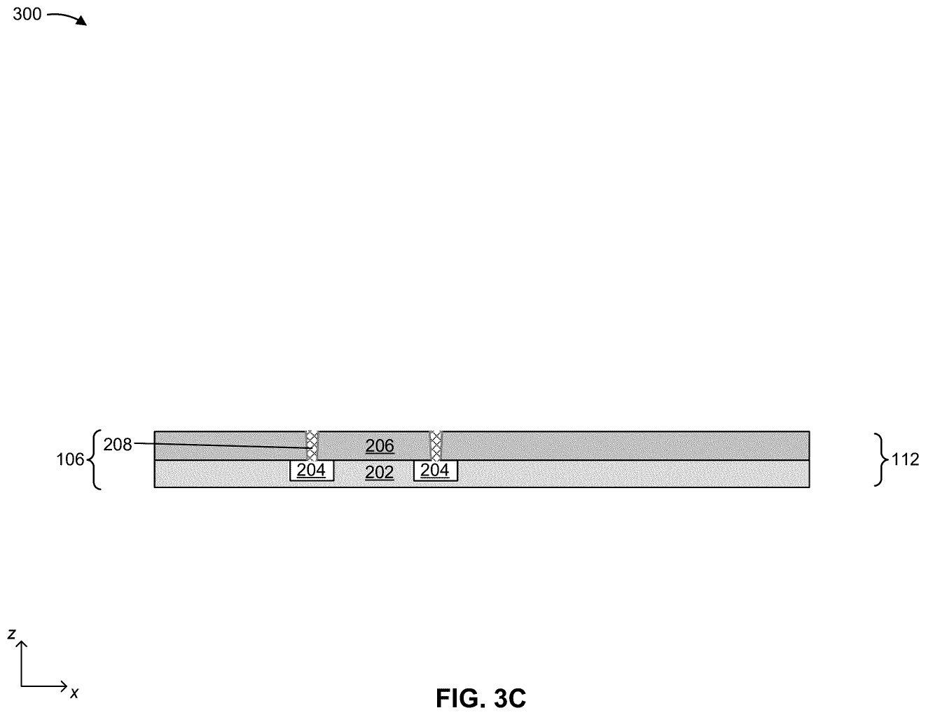

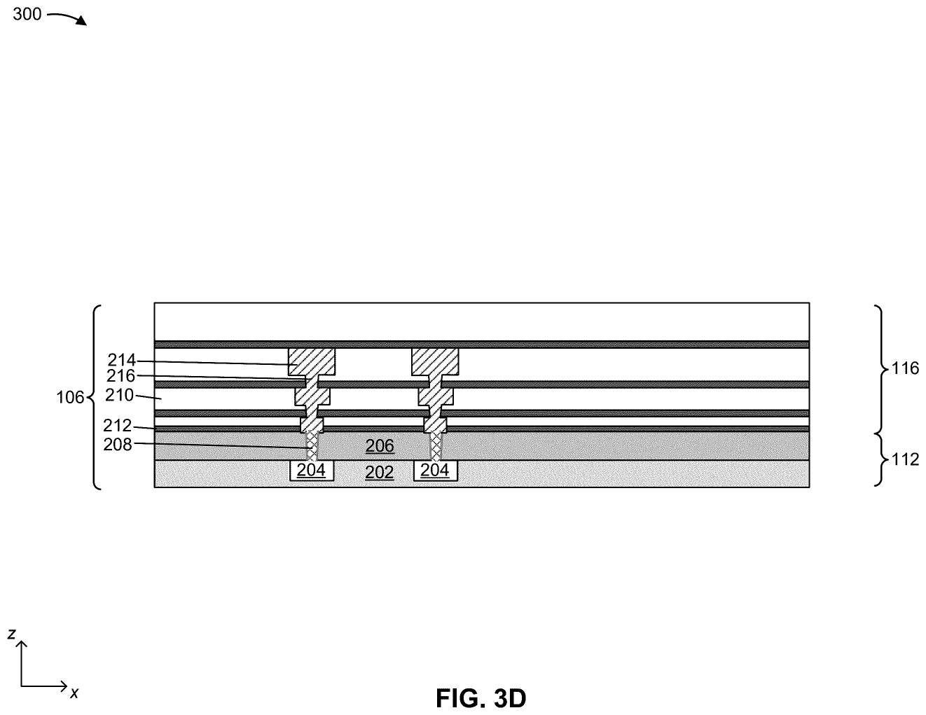

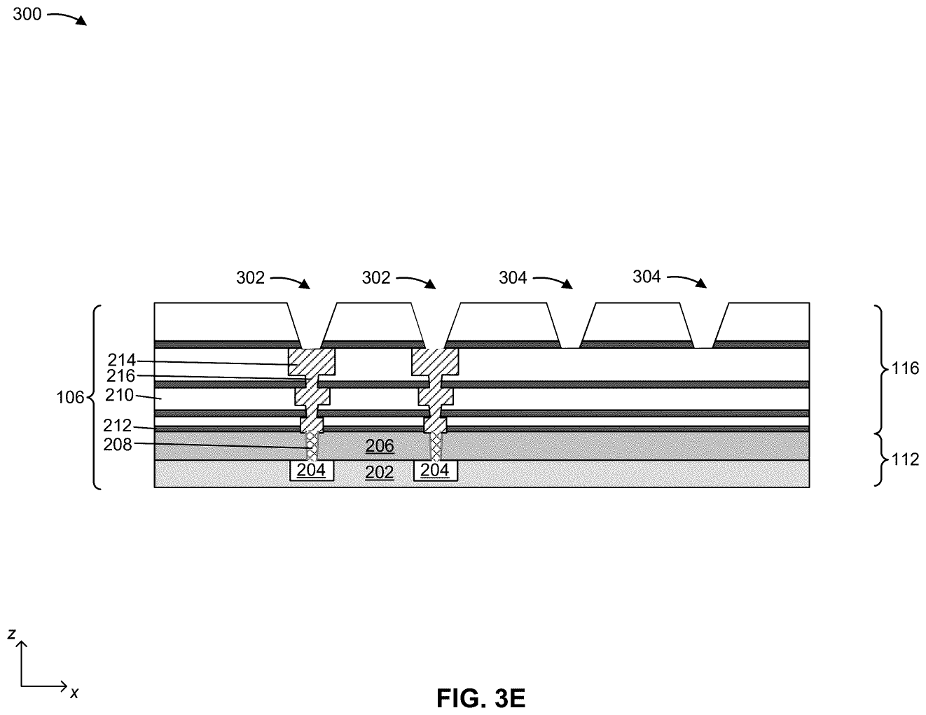

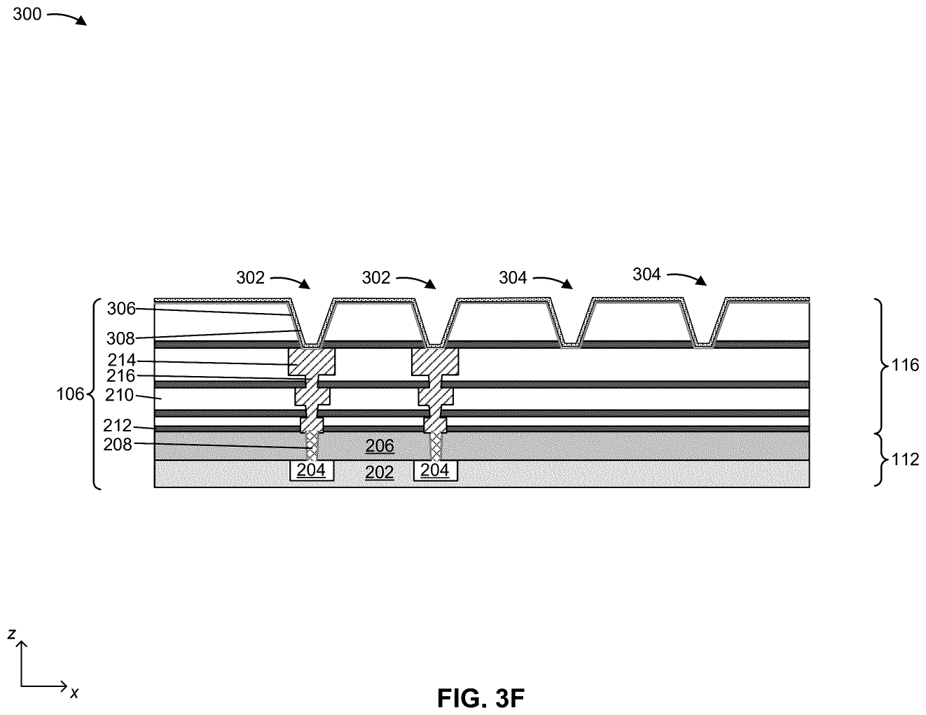

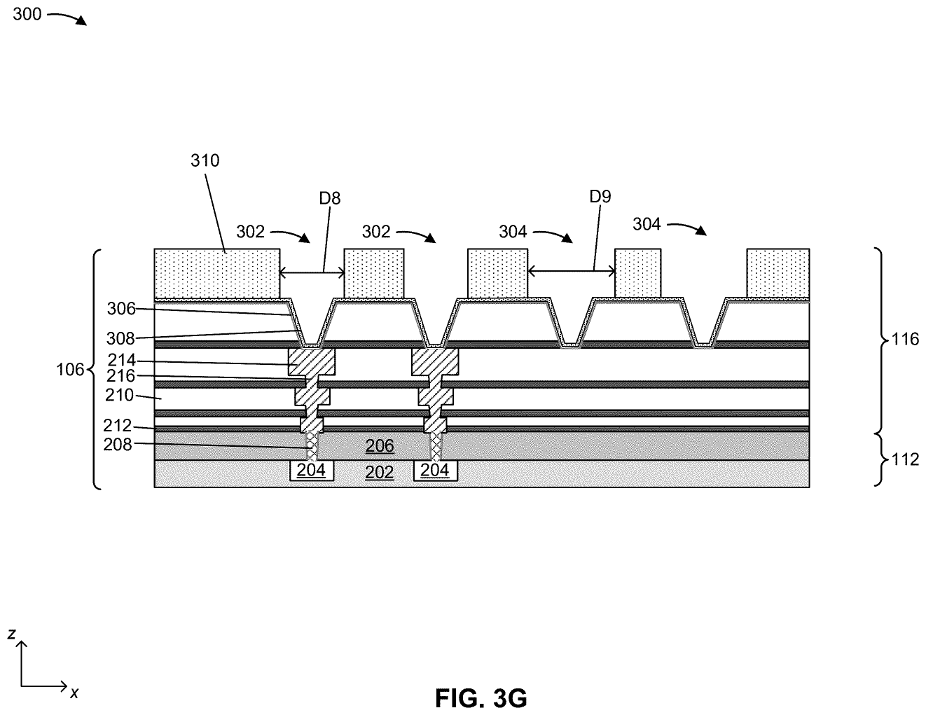

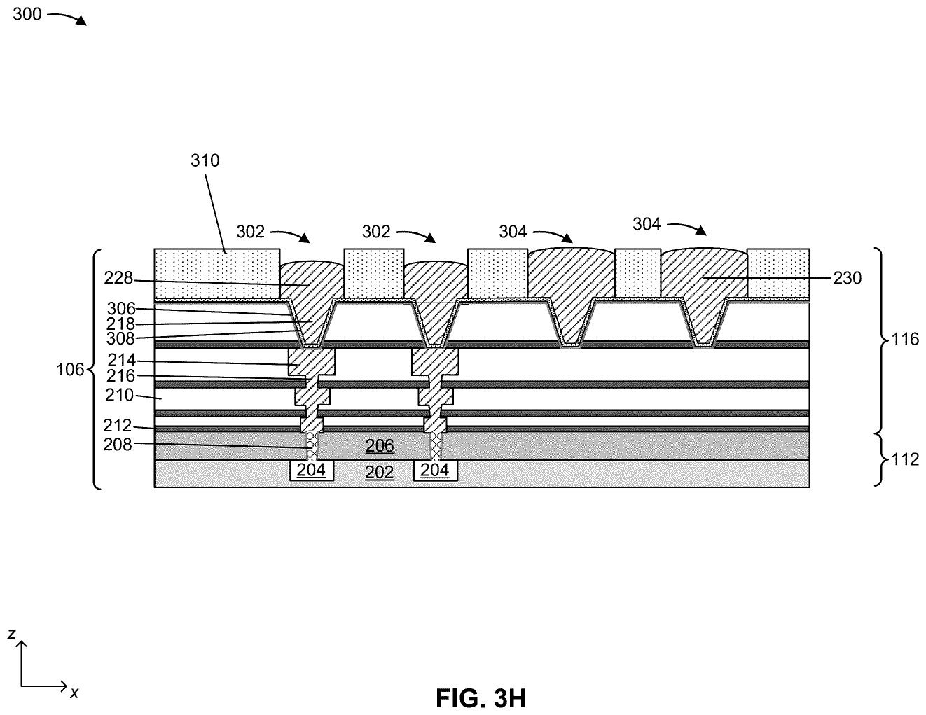

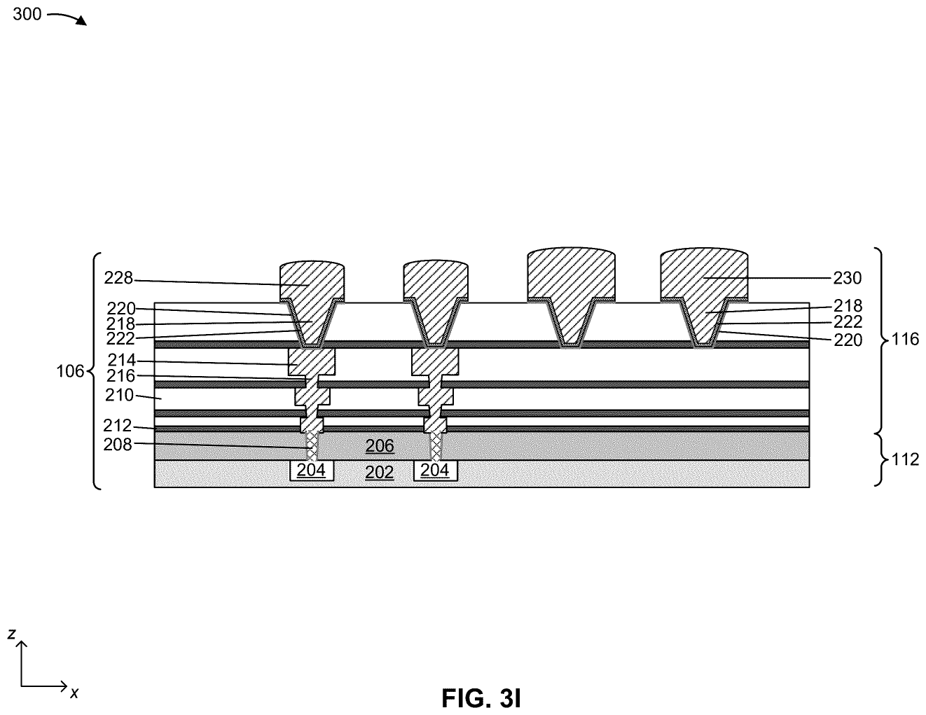

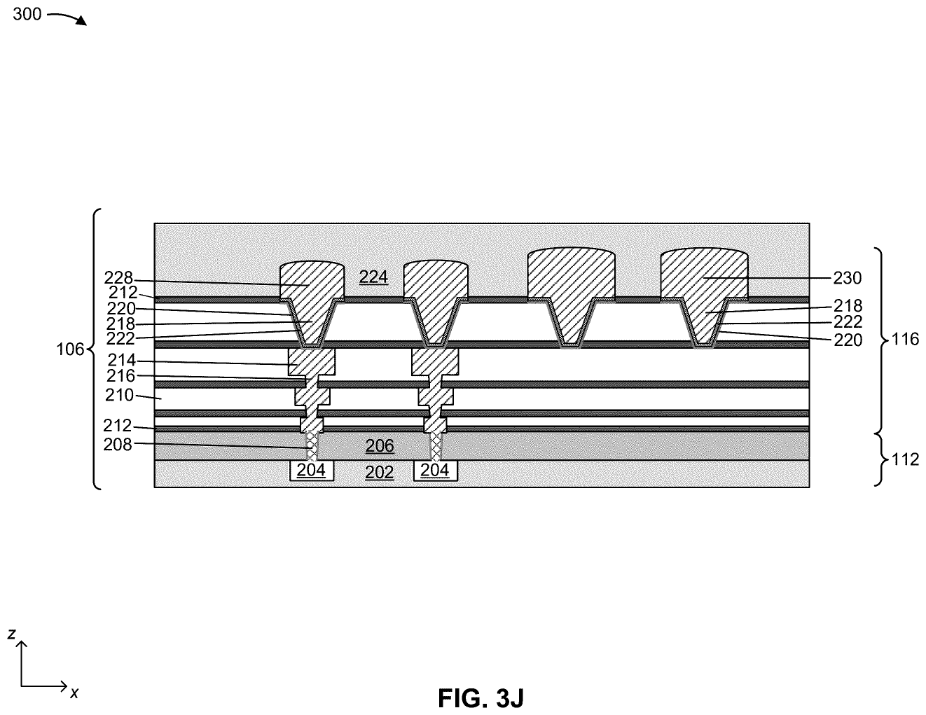

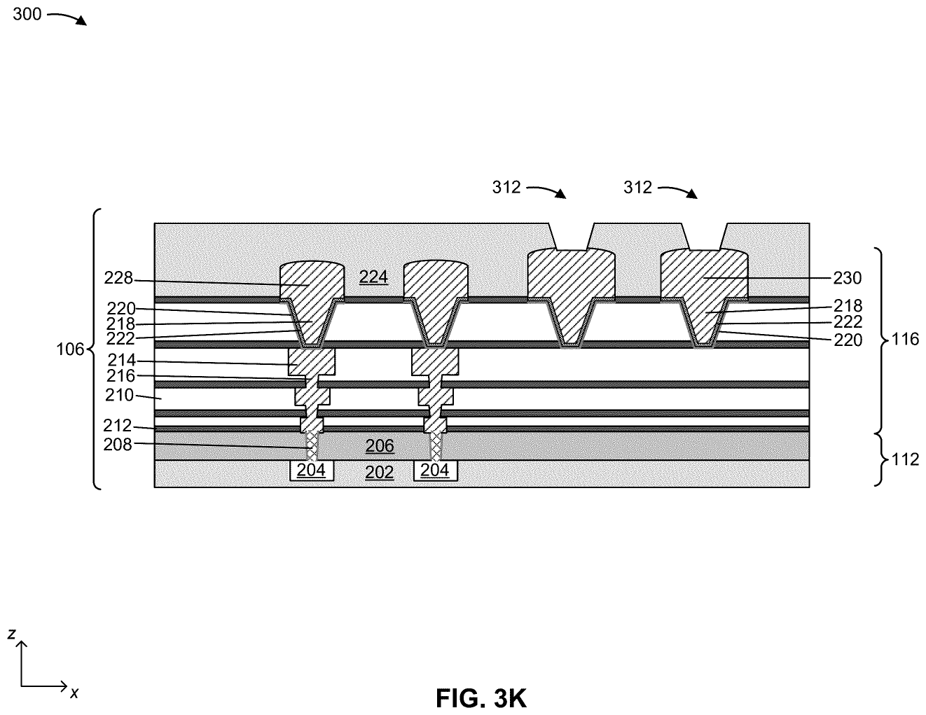

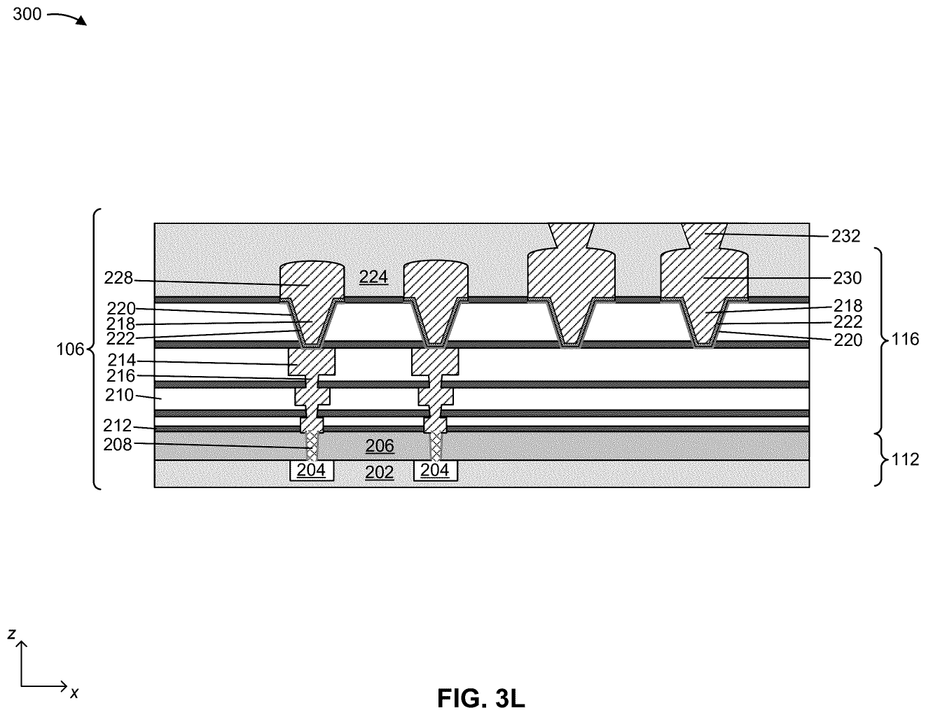

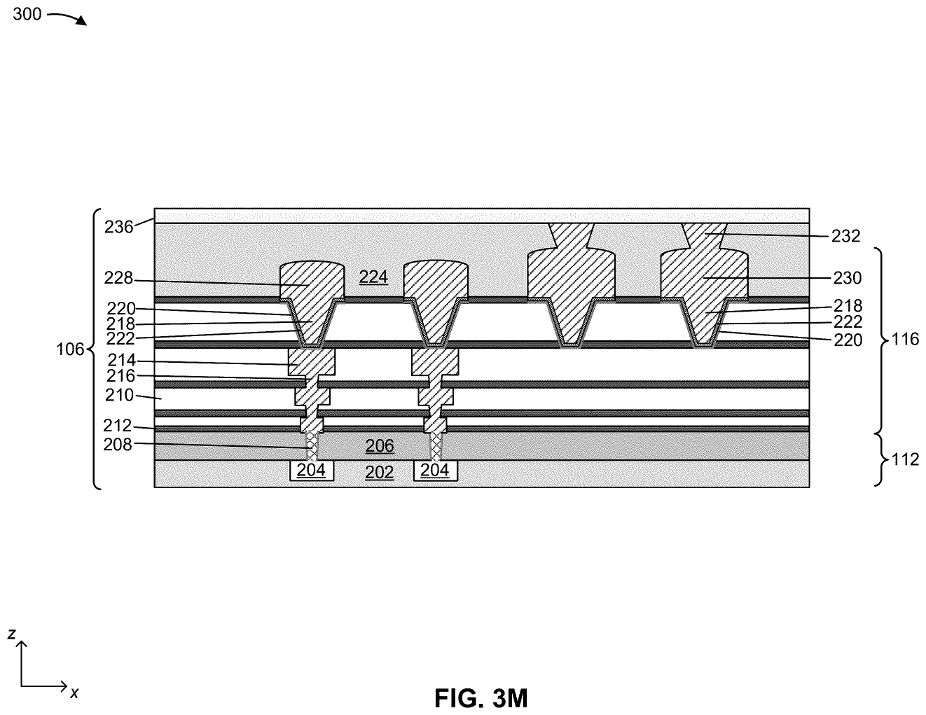

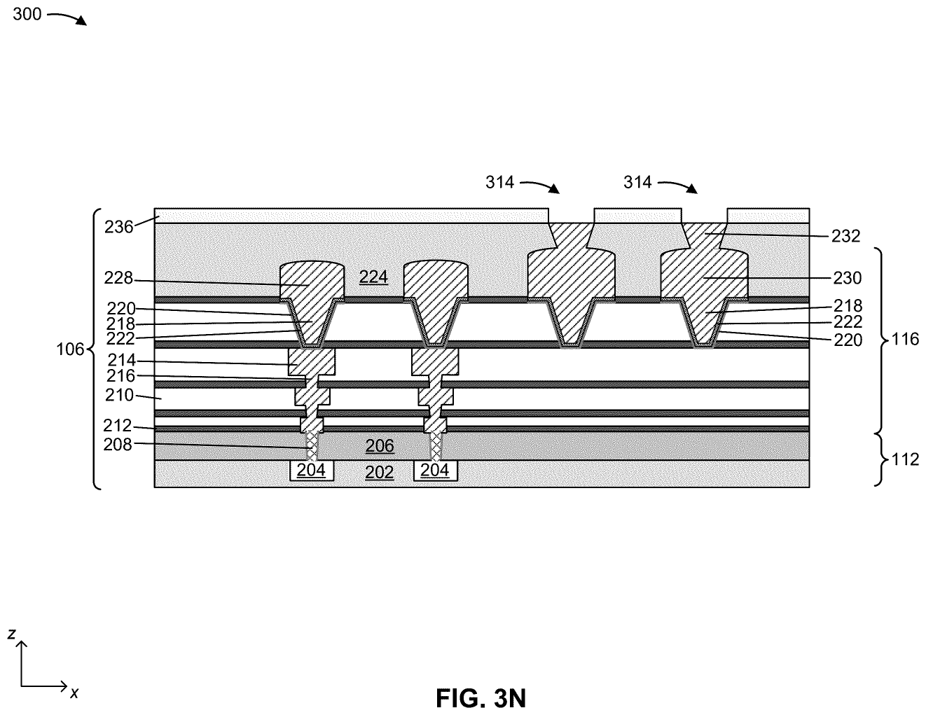

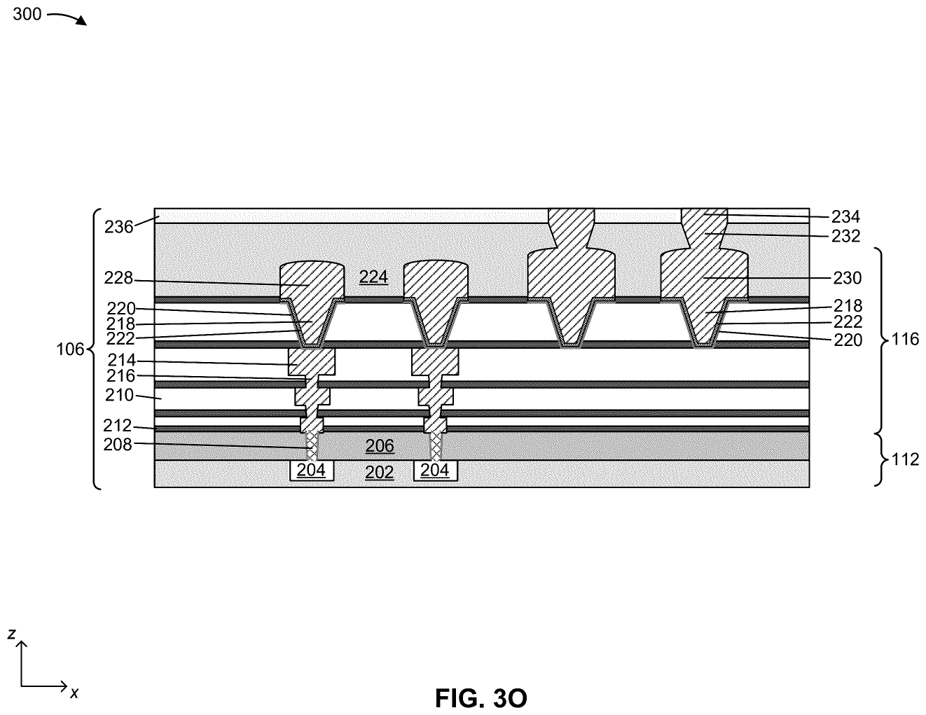

FIGS. 3A-3O are diagrams of an example implementation 300 of forming a semiconductor die 106 described herein. In some implementations, one or more of the semiconductor processing tools may be used to perform one or more of the semiconductor processing operations described in connection with FIGS. 3A-3O, such as a deposition tool, an exposure tool, a developer tool, an etch tool, an ion implantation tool, and/or a wafer/die transport tool, among other examples. In some implementations, one or more of the operations and/or techniques described in the example implementation 300 of forming a semiconductor die 106 may also be performed or used to form a semiconductor die 108.

Turning to FIG. 3A, the substrate 202 may be provided. The substrate 202 may be provided in the form of a semiconductor wafer (e.g., the semiconductor wafer 102) such as a silicon (Si) wafer. The semiconductor die 106 may be formed on the substrate 202 along with a plurality of other semiconductor dies 106.

As shown in FIG. 3B, the integrated circuit devices 204 may be formed in and/or on the substrate 202 in the device layer 112 of the semiconductor die 106. One or more semiconductor processing tools may be used to form one or more portions of the integrated circuit devices 204. For example, a deposition tool may be used to perform various deposition operations to deposit layers of the integrated circuit devices 204, and/or to deposit photoresist layers for etching the substrate 202 and/or portions of the deposited layers. As another example, an exposure tool may be used to expose the photoresist layers to form patterns in the photoresist layers. As another example, a developer tool may develop the patterns in the photoresist layers. As another example, an etch tool may be used to etch the substrate 202 and/or portions of the deposited layers to form the integrated circuit devices 204. As another example, a planarization tool may be used to planarize portions of the integrated circuit devices 204. As another example, an ion implantation tool may be used to implant ions in the substrate 202 to dope portions of the substrate 202 with one or more types of dopants (e.g., p-type dopants, n-type dopants).

As shown in FIG. 3C, a deposition tool is used to deposit the dielectric layer 206 over and/or on the substrate 202 and over and/or on the integrated circuit devices 204. A deposition tool, an exposure tool, and a developer tool may be used to form a patterned masking layer (e.g., a patterned photoresist layer, a patterned hard mask layer) on the dielectric layer 206. An etch tool may be used to form recesses in the dielectric layer 206, and a deposition tool may be used to form contacts 208 in the recesses such that the contacts 208 are physically coupled and/or electrically coupled with the integrated circuit devices 204.

As shown in FIG. 3D, a first portion of the interconnect layer 116 is formed above the device layer 112. Forming the first portion of the interconnect layer 116 may include forming a plurality of alternating layers of backend dielectric layers 210 and ESLs 212, and forming alternating layers of conductive structures 214 and interconnect structures 216.

The first portion of the interconnect layer 116 may be manufactured in series of sequential layers. For example, a deposition tool may be used to deposit an ESL 212 and a backend dielectric layer 210 each using a physical vapor deposition (PVD) technique, an atomic layer deposition (ALD) technique, a chemical vapor deposition (CVD) technique, an oxidation technique, and/or another deposition technique. In some implementations, a planarization tool is used to planarize the ESL 212 and/or the backend dielectric layer 210. Recesses may be formed in and/or through the ESL 212 and the backend dielectric layer 210, and a deposition tool may be used to deposit an interconnect structure 216 and a conductive structure 214 in each of the recesses. The preceding set of operations may be repeated for each subsequent layer of the first portion of the interconnect layer 116. In some implementations, dual damascene processes are used for forming the layers of the first portion of the interconnect layer 116.

As shown in FIG. 3E, recesses 302 and 304 are formed in and/or through a backend dielectric layer 210 and an underlying ESL 212. The top surfaces of one or more of the topmost conductive structures 214 in the interconnect layer 116 are exposed through one or more of the recesses 302. A deposition tool may be used to form a photoresist layer on the topmost backend dielectric layer 210. An exposure tool may be used to expose the photoresist layer to a radiation source to pattern the photoresist layer. A developer tool may be used to develop and remove portions of the photoresist layer to expose the pattern. An etch tool may be used to etch the topmost backend dielectric layer 210 and the underlying ESL 212 to form the recesses 302 and 304. In some implementations, a photoresist removal tool removes the remaining portions of the photoresist layer (e.g., using a chemical stripper and/or another technique).

As shown in FIG. 3F, a deposition tool may be used to deposit conformal layers 306 and 308 in the recesses 302 and 304. The conformal layers 306 and 308 may also be deposited on the top surface of the topmost backend dielectric layer 210. The conformal layers 306 and 308 may be subsequently etched to form barrier layers 220 and/or adhesion layers 222. A conformal deposition technique such as ALD may be used to conformally deposit the conformal layers 306 and 308. Alternatively, a CVD technique and/or another suitable deposition technique may be used to deposit the conformal layers 306 and 308.

As shown in FIG. 3G, a patterned masking layer 310 is formed over the topmost backend dielectric layer 210 such that openings through the patterned masking layer 310 are formed above the recesses 302 and 304. This essentially enables the depth of the recesses 302 and 304 to be increased without further etching into the interconnect layer 116. A deposition tool may be used to form a photoresist layer over the topmost backend dielectric layer 210. An exposure tool may be used to expose the photoresist layer to a radiation source to pattern the photoresist layer. A developer tool may be used to develop and remove portions of the photoresist layer to expose the pattern, resulting in formation of the patterned masking layer 310.

As further shown in FIG. 3G, the width of a recess 302 (corresponding to dimension D8) at the height of the patterned masking layer 310 is greater than a width of the recess 302 at the height of the topmost backend dielectric layer 210. In other words, the opening through the patterned masking layer 310 above the recess 302 laterally extends outward past the opening of the recess 302 in the topmost backend dielectric layer 210. This creates a dual damascene recess, where the portion of the recess 302 in the topmost backend dielectric layer 210 is the via portion of the dual damascene recess, and the portion of the recess 302 in the patterned masking layer 310 is the trench portion of the dual damascene recess. This enables a top interconnect structure 218 and an associated top conductive structure 228 to be formed in the recess 302 in the same deposition operation (or same set of deposition operations).

Similarly, the width of a recess 304 (corresponding to dimension D9) at the height of the patterned masking layer 310 is greater than a width of the recess 304 at the height of the topmost backend dielectric layer 210. In other words, the opening through the patterned masking layer 310 above the recess 304 laterally extends outward past the opening of the recess 304 in the topmost backend dielectric layer 210. This creates a dual damascene recess, where the portion of the recess 304 in the topmost backend dielectric layer 210 is the via portion of the dual damascene recess, and the portion of the recess 304 in the patterned masking layer 310 is the trench portion of the dual damascene recess. This enables a top interconnect structure 218 and an associated top conductive structure 230 to be formed in the recess 304 in the same deposition operation (or same set of deposition operations). The dimension D9 is greater than the dimension D8, which enables the top conductive structures 230 to be formed to a greater cross-sectional width than the top conductive structures 228.

As shown in FIG. 3H, a deposition tool may be used to deposit the top interconnect structures 218 and the top conductive structures 228 on the top interconnect structures 218 in the recesses 302. Moreover, the deposition tool may be used to deposit the top interconnect structures 218 and the top conductive structures 230 on the top interconnect structures 218 in the recesses 304. A CVD technique, a PVD technique, an ALD technique, an electroplating technique, and/or another suitable deposition technique may be used to deposit the top interconnect structures 218, the top conductive structures 228, and the top conductive structures 230. The top interconnect structures 218 may be deposited on the conformal layer 308, which may be an adhesion layer or a seed layer.

Since the patterned masking layer 310 is used to form the top conductive structures 228 and 230, a planarization operation is omitted for the top conductive structures 228 and 230. This enables the top conductive structures 228 and 230 to be formed to different heights, such that the height of the top conductive structures 230 is greater than the height of the top conductive structures 228. As a result, the top conductive structures 228 and 230 have non-planar (e.g., rounded or curved) top surfaces. Moreover, forming the top conductive structures 228 and 230 means that the top conductive structures 228 and 230 (and the associated top interconnect structures 218) are formed prior to formation of the backend dielectric layer 224. The different heights top conductive structures 228 and 230 may occur due to the different widths of the top conductive structures 228 and 230. The greater width of the top conductive structures 230 provides a greater area in the recesses 304 in which to capture material from the deposition process (e.g., the electroplating process or the electrochemical plating process) than the recesses 302. This results in material from the deposition process accumulating at a faster rate in the recesses 304 than in the recesses 302, resulting in the top conductive structures 230 growing in height/thickness at a faster rate than the top conductive structures 228.

As shown in FIG. 3I, the patterned masking layer 310 is removed after formation of the top conductive structures 228 and 230 and the associated top interconnect structures 218. An etch tool may be used to remove the patterned masking layer 310. An etchant that has a low etch rate for copper (or that does not etch copper) or the material of the top conductive structures 228 and 230 may be used to remove the patterned masking layer 310. In some implementations, over-etching may occur when etching the patterned masking layer 310, such that portions of the conformal layers 306 and 308 that are not under the top interconnect structures 218 are also removed. This results in formation of the individual barrier layers 220 (e.g., from the conformal layer 306) and the individual adhesion layers 222 (e.g., from the conformal layer 308) under the top interconnect structures 218.

As shown in FIG. 3J, another ESL 212 is formed, and the backend dielectric layer 224 is formed on the ESL 212 and over the top conductive structures 228 and 230 such that the top conductive structures 228 and 230 are encapsulated in the backend dielectric layer 224. In other words, the top surface of the backend dielectric layer 224 is at a greater z-direction height than the top surfaces of the top conductive structures 228 and 230, such that the top conductive structures 228 and 230 are fully covered by the backend dielectric layer 224. A deposition tool, using a PVD technique, an ALD technique, a CVD technique, an oxidation technique, and/or another type of deposition technique, may be used to deposit each of the ESL 212 and the backend dielectric layer 224. In some implementations, a planarization tool is used to planarize the top surface of the backend dielectric layer 224.

As shown in FIG. 3K, recesses 312 are formed in the backend dielectric layer 224 over the top conductive structures 230. The recesses 312 may extend through the backend dielectric layer 224 to the top conductive structures 230 such that the top surfaces of the top conductive structures 230 are exposed through the recesses 312 in the backend dielectric layer 224. In some implementations, over-etching may occur to ensure that the backend dielectric layer 224 is fully etched through to top surfaces of the top conductive structures 230. In these implementations, some etching may occur into the top surfaces of the top conductive structures 230.

The recesses 312 may be formed in preparation for forming bonding vias 232 in the recesses 312. Since bonding vias 232 are omitted from the top conductive structures 228, the recesses 312 are formed while the top conductive structures 228 are still encapsulated and covered by the backend dielectric layer 224.

In some implementations, a pattern in a photoresist layer is used to etch the backend dielectric layer 224 to form the recesses 312. In these implementations, a deposition tool may be used to form the photoresist layer on the backend dielectric layer 224. An exposure tool may be used to expose the photoresist layer to a radiation source to pattern the photoresist layer. A developer tool may be used to develop and remove portions of the photoresist layer to expose the pattern. An etch tool may be used to etch the backend dielectric layer 224 based on the pattern to remove the portions of the backend dielectric layer 224 above the top conductive structures 230 (and not from above the top conductive structures 228). In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the backend dielectric layer 224 based on a pattern.

As shown in FIG. 3L, the bonding vias 232 are formed on the top conductive structures 230. The bonding vias 232 are formed in the recesses 312 through the backend dielectric layer 224. A deposition tool may be used to deposit the bonding vias 232 using a CVD technique, a PVD technique, an ALD technique, an electroplating technique, and/or another suitable deposition technique. In some implementations, a planarization tool is used to planarize the bonding vias 232 after the bonding vias 232 are deposited such that the top surfaces of the bonding vias 232 are approximately co-planar with the top surface of the backend dielectric layer 224.

As shown in FIG. 3M, the bonding dielectric layer 236 is formed on the backend dielectric layer 224 and on the bonding vias 232. A deposition tool may be used to deposit the bonding dielectric layer 236 using a CVD technique, a PVD technique, an ALD technique, an oxidation technique, and/or another suitable deposition technique. In some implementations, a planarization tool is used to planarize the bonding dielectric layer 236 after the bonding dielectric layer 236 is deposited.

As shown in FIG. 3N, recesses 314 are formed in the bonding dielectric layer 236 over the bonding vias 232. The recesses 314 may extend through the bonding dielectric layer 236 to the bonding vias 232 such that the top surfaces of the bonding vias 232 are exposed through the recesses 314 in the bonding dielectric layer 236.

In some implementations, a pattern in a photoresist layer is used to etch the bonding dielectric layer 236 to form the recesses 314. In these implementations, a deposition tool may be used to form the photoresist layer on the bonding dielectric layer 236. An exposure tool may be used to expose the photoresist layer to a radiation source to pattern the photoresist layer. A developer tool may be used to develop and remove portions of the photoresist layer to expose the pattern. An etch tool may be used to etch the bonding dielectric layer 236 based on the pattern to remove the portions of the bonding dielectric layer 236 above the bonding vias 232 to form the recesses 314. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the bonding dielectric layer 236 based on a pattern.

As shown in FIG. 3O, the bonding pads 234 are formed on the bonding vias 232. The bonding pads 234 are formed in the recesses 314 through the bonding dielectric layer 236. A deposition tool may be used to deposit the bonding pads 234 using a CVD technique, a PVD technique, an ALD technique, an electroplating technique, and/or another suitable deposition technique. In some implementations, a planarization tool is used to planarize the bonding pads 234 after the bonding pads 234 are deposited such that the top surfaces of the bonding pads 234 are approximately co-planar with the top surface of the bonding dielectric layer 236.

As indicated above, FIGS. 3A-3O are provided as an example. Other examples may differ from what is described with regard to FIGS. 3A-3O.

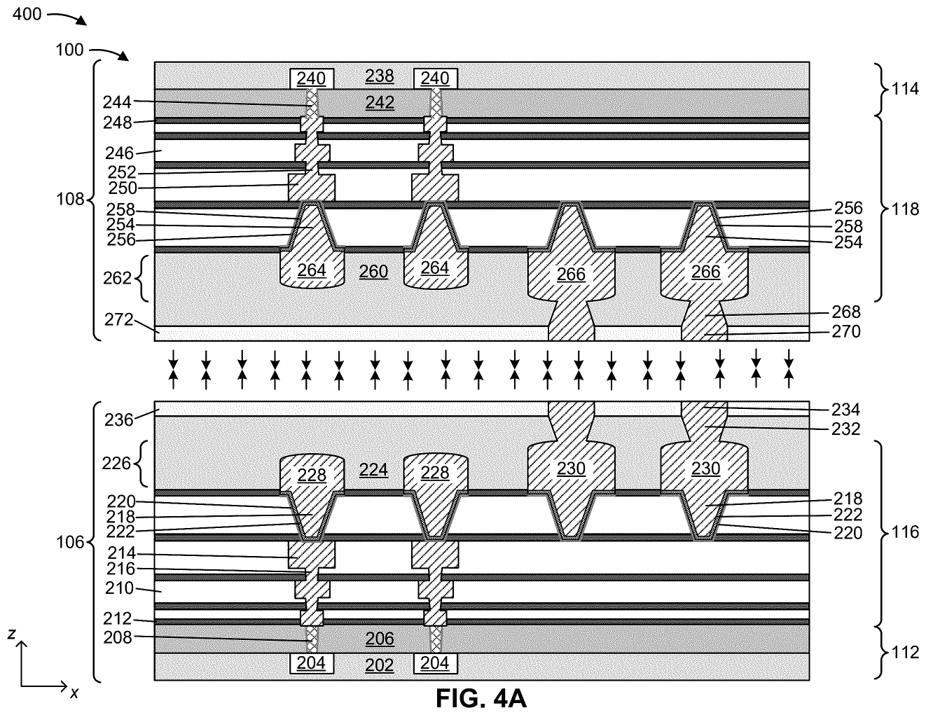

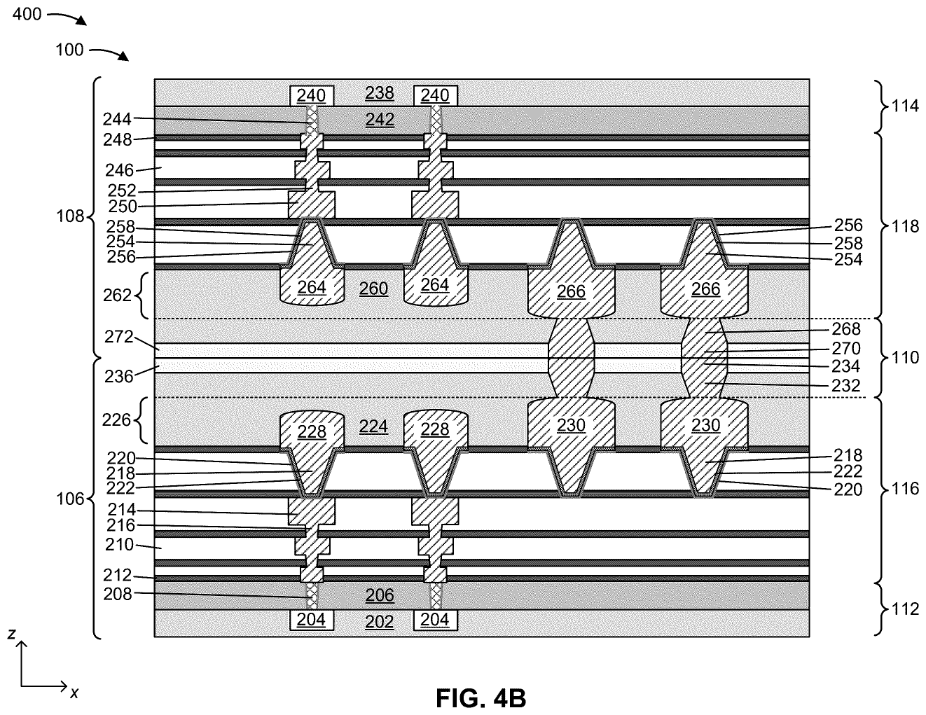

FIGS. 4A and 4B are diagrams of an example implementation 400 of forming a semiconductor device 100 described herein. In particular, the example implementation 400 includes an example of bonding the semiconductor die 106 and the semiconductor die 108 to form the semiconductor device 100.

As shown in 4A and 4B, a bonding operation is performed to bond the semiconductor die 106 and the semiconductor die 108 at the bonding interface 110 such that the semiconductor die 106 and the semiconductor die 108 are vertically arranged or stacked in the z-direction in the semiconductor device 100. The semiconductor die 106 and the semiconductor die 108 may be vertically arranged or stacked in a wafer on wafer (WoW) configuration, a die on wafer configuration, a die on die configuration, and/or another direct bonding configuration. A bonding tool may be used to perform the bonding operation to bond the semiconductor die 106 and the semiconductor die 108 at the bonding interface 110. The bonding operation may include forming a direct bond between the semiconductor die 106 and the semiconductor die 108 through a direct physical connection of the bonding pads 234 of the semiconductor die 106 with the bonding pads 270 of the semiconductor die 108, and through a direct physical connection of the bonding dielectric layer 236 of the semiconductor die 106 with bonding dielectric layer 272 of the semiconductor die 108.

Bonding of the bonding pads 234 and 270 results in an electrical connection between the top conductive structures 230 of the semiconductor die 106 and the top conductive structures 266 of the semiconductor die 108 through the bonding pads 234 and 270 and the bonding vias 232 and 268. Since bonding pads or bonding vias are free from above the top conductive structures 228 and 264, the backend dielectric layers 224 and 260, and the bonding dielectric layers 236 and 272, are included between the top conductive structures 228 and 264.

In some implementations, the semiconductor die 106 and the semiconductor die 108 are bonded as part of bonding the semiconductor wafer 102 and the semiconductor wafer 104 in the bonding operation. Accordingly, the semiconductor device 100 (and other semiconductor devices 100) may be diced or cut from the bonded semiconductor wafer 102 and the semiconductor wafer 104 and packaged.

As indicated above, FIGS. 4A and 4B are provided as an example. Other examples may differ from what is described with regard to FIGS. 4A and 4B.

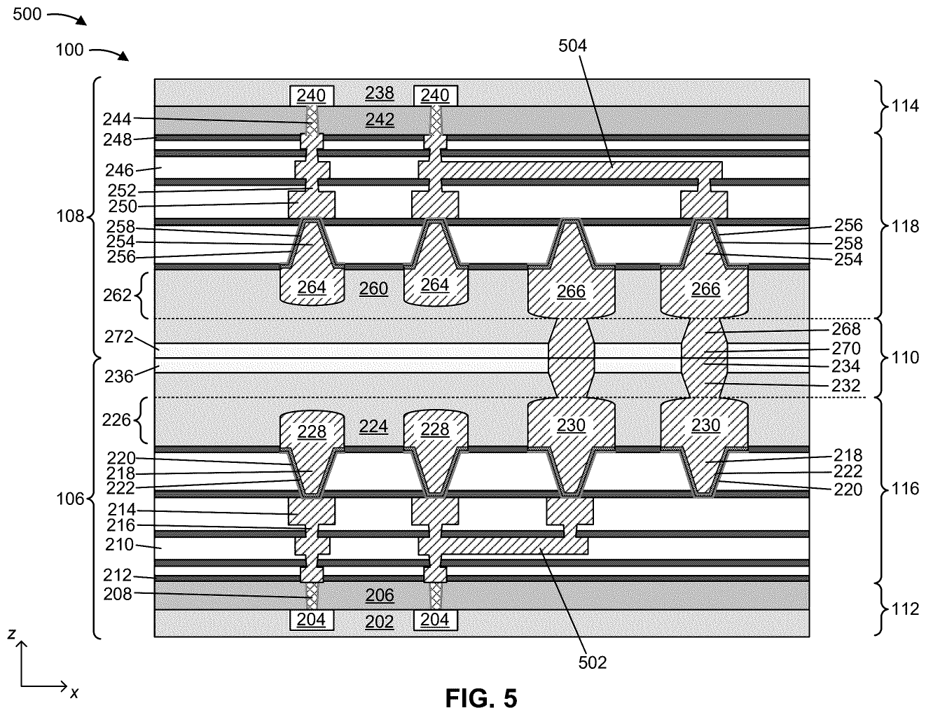

FIG. 5 is a diagram of an example 500 of a semiconductor device 100 described herein. FIG. 5 illustrates a cross-sectional view of the semiconductor device 100. As shown in FIG. 5, the example 500 of the semiconductor device 100 is similar to the example 200 of the semiconductor device illustrated and described in connection with FIG. 2A. However, the example 500 of a semiconductor device 100 includes one or more connecting structures 502 in the interconnect layer 116 of the semiconductor die 106 (e.g., as opposed to, or in addition to the connecting structures 276). The connecting structure(s) 502 may correspond to one or more conductive structures 214 below the top interconnect structures 218 and the top conductive structures 228 and 230. The connecting structure(s) 502 may electrically connect a top conductive structure 228 and a top conductive structure 230 through one or more conductive structures 214, one or more interconnect structures 216, and/or one or more top interconnect structures 218. This enables signals and/or power to be routed between the top conductive structure 228 and the top conductive structure 230. Moreover, the connecting structure(s) 502 enable(s) signals and/or power to be routed between the top conductive structure 228 and the semiconductor die 108 through the top conductive structure 230.

Additionally and/or alternatively, the example 500 of a semiconductor device 100 includes one or more connecting structures 504 in the interconnect layer 118 of the semiconductor die 108 (e.g., as opposed to, or in addition to the connecting structures 276). The connecting structure(s) 504 may correspond to one or more conductive structures 250 above the top interconnect structures 254 and the top conductive structures 264 and 266. The connecting structure(s) 504 may electrically connect a top conductive structure 264 and a top conductive structure 266 through one or more conductive structures 250, one or more interconnect structures 252, and/or one or more top interconnect structures 254. This enables signals and/or power to be routed between the top conductive structure 264 and the top conductive structure 266. Moreover, the connecting structure(s) 504 enable(s) signals and/or power to be routed between the top conductive structure 264 and the semiconductor die 106 through the top conductive structure 266.

As indicated above, FIG. 5 is provided as an example. Other examples may differ from what is described with regard to FIG. 5.

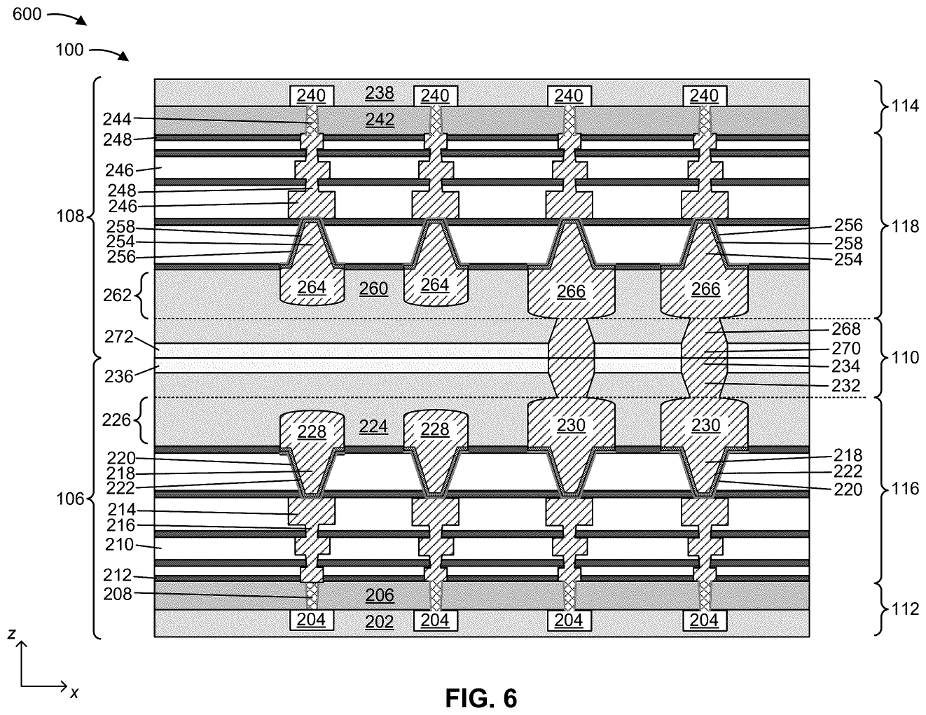

FIG. 6 is a diagram of an example 600 of a semiconductor device 100 described herein. FIG. 6 illustrates a cross-sectional view of the semiconductor device 100. As shown in FIG. 6, the example 600 of the semiconductor device 100 is similar to the example 200 of the semiconductor device illustrated and described in connection with FIG. 2A. However, the example 600 of a semiconductor device 100 includes conductive structures 214 and interconnect structures 216 in the interconnect layer 116 of the semiconductor die 106 that electrically connect one or more top conductive structures 230 to one or more integrated circuit devices 204 in the device layer 112 of the semiconductor die 106. This enables signals and/or power to be routed between the integrated circuit devices 204 and the semiconductor die 108 through the conductive structure(s) 230.

Additionally and/or alternatively, the example 600 of a semiconductor device 100 includes conductive structures 250 and interconnect structures 252 in the interconnect layer 118 of the semiconductor die 108 that electrically connect one or more top conductive structures 266 to one or more integrated circuit devices 240 in the device layer 114 of the semiconductor die 108. This enables signals and/or power to be routed between the integrated circuit devices 240 and the semiconductor die 106 through the top conductive structure(s) 266.

As indicated above, FIG. 6 is provided as an example. Other examples may differ from what is described with regard to FIG. 6.

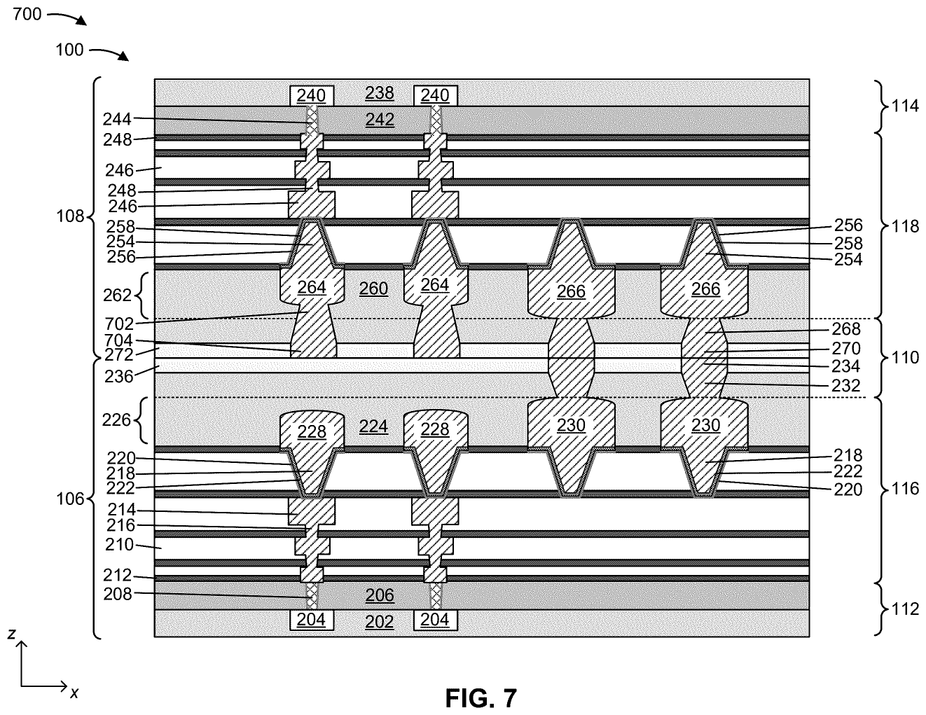

FIG. 7 is a diagram of an example 700 of a semiconductor device 100 described herein. FIG. 7 illustrates a cross-sectional view of the semiconductor device 100. As shown in FIG. 7, the example 700 of the semiconductor device 100 is similar to the example 200 of the semiconductor device illustrated and described in connection with FIG. 2A. However, the example 700 of a semiconductor device 100 includes bonding vias 702 in physical contact with the top conductive structures 264 of the semiconductor die 108, and bonding pads 704 in physical contact with the bonding vias 702. As shown in FIG. 7, the bonding pads 704 and bonding vias 702 are not connected with bonding pads and bonding vias in the semiconductor die 106 because bonding pads and bonding vias are omitted from the top conductive structures 228 in the semiconductor die 106. However, the bonding pads 704 and bonding vias 702 may provide additional metallization layers in the semiconductor die 108 for routing signals and/or power within the semiconductor die 108.

As indicated above, FIG. 7 is provided as an example. Other examples may differ from what is described with regard to FIG. 7.

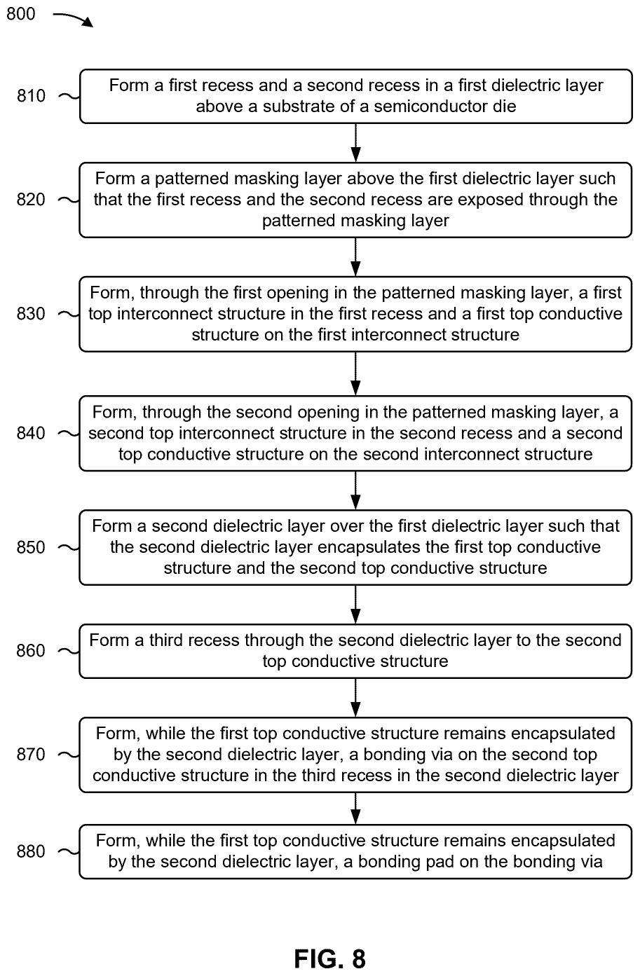

FIG. 8 is a flowchart of an example process 800 associated with forming a semiconductor device described herein. In some implementations, one or more process blocks of FIG. 8 are performed using one or more semiconductor processing tools.

As shown in FIG. 8, process 800 may include forming a first recess and a second recess in a first dielectric layer above a substrate of a semiconductor die (block 810). For example, one or more semiconductor processing tools may be used to form a first recess 302 and a second recess 304 in a first dielectric layer (e.g., a backend dielectric layer 210) above a substrate 202 of a semiconductor die 106, as described herein.

As further shown in FIG. 8, process 800 may include forming a patterned masking layer above the first dielectric layer such that the first recess and the second recess are exposed through the patterned masking layer (block 820). For example, one or more semiconductor processing tools may be used to form a patterned masking layer 310 above the first dielectric layer (e.g., the backend dielectric layer 210) such that the first recess 302 and the second recess 304 are exposed through the patterned masking layer 310, as described herein. In some implementations, a first width (e.g., dimension D8) of a first opening in the patterned masking layer 310 above the first recess 302 is less than a second width (e.g., dimension D9) of a second opening in the patterned masking layer 310 above the second recess 304.

As further shown in FIG. 8, process 800 may include forming, through the first opening in the patterned masking layer, a first top interconnect structure in the first recess and a first top conductive structure on the first top interconnect structure (block 830). For example, one or more semiconductor processing tools may be used to form, through the first opening in the patterned masking layer 310, a first top interconnect structure 218 in the first recess 302 and a first top conductive structure 228 on the first top interconnect structure 218, as described herein.

As further shown in FIG. 8, process 800 may include forming, through the second opening in the patterned masking layer, a second top interconnect structure in the second recess and a second top conductive structure on the second top interconnect structure (block 840). For example, one or more semiconductor processing tools may be used to form, through the second opening in the patterned masking layer 310, a second top interconnect structure 218 in the second recess 304 and a second top conductive structure 230 on the second top interconnect structure 218, as described herein.

As further shown in FIG. 8, process 800 may include forming a second dielectric layer on the first dielectric layer such that the second dielectric layer encapsulates the first top conductive structure and the second top conductive structure (block 850). For example, one or more semiconductor processing tools may be used to form a second dielectric layer (e.g., a backend dielectric layer 224) over the first dielectric layer (e.g., the backend dielectric layer 210) such that the second dielectric layer encapsulates the first top conductive structure 228 and encapsulates the second top conductive structure 230, as described herein.

As further shown in FIG. 8, process 800 may include forming a third recess through the second dielectric layer to the second top conductive structure (block 860). For example, one or more semiconductor processing tools may be used to form a third recess 312 through the second dielectric layer (e.g., the backend dielectric layer 224) to the second top conductive structure 230, as described herein. In some implementations, the first top conductive structure remains encapsulated by the second dielectric layer while the third recess 312 is formed.

As further shown in FIG. 8, process 800 may include forming, while the first top conductive structure remains encapsulated by the second dielectric layer, a bonding via on the second top conductive structure in the third recess in the second dielectric layer (block 870). For example, one or more semiconductor processing tools may be used to form, while the first top conductive structure 228 remains encapsulated by the second dielectric layer (e.g., the backend dielectric layer 224), a bonding via 232 on the second top conductive structure 230 in the third recess 312 in the second dielectric layer, as described herein.

As further shown in FIG. 8, process 800 may include forming, while the first top conductive structure remains encapsulated by the second dielectric layer, a bonding pad on the bonding via (block 880). For example, one or more semiconductor processing tools may be used to form, while the first top conductive structure 228 remains encapsulated by the second dielectric layer (e.g., the backend dielectric layer 224), a bonding pad 234 on the bonding via 232, as described herein.

Process 800 may include additional implementations, such as any single implementation or any combination of implementations described below and/or in connection with one or more other processes described elsewhere herein.

In a first implementation, process 800 includes forming a bonding dielectric layer 236 on the second dielectric layer (e.g., the backend dielectric layer 224), and forming a fourth recess 314 in the bonding dielectric layer 236, where forming the bonding pad 234 includes forming the bonding pad 234 on the bonding via 232 in the fourth recess 314 in the bonding dielectric layer 236.

In a second implementation, alone or in combination with the first implementation, forming the first top conductive structure 228 includes forming the first top conductive structure 228 to a first height (e.g., dimension D3), and forming the second top conductive structure 230 includes forming the second top conductive structure 230 to a second height (e.g., dimension D4) that is greater than the first height.

In a third implementation, alone or in combination with one or more of the first and second implementations, process 800 includes removing the patterned masking layer 310 after forming the first top interconnect structure 218, the second top interconnect structure 218, the first top conductive structure 228, and the second top conductive structure 230, and forming the second dielectric layer (e.g., the backend dielectric layer 224) includes forming the second dielectric layer in areas of the semiconductor die that were previously occupied by the patterned masking layer 310.

In a fourth implementation, alone or in combination with one or more of the first through third implementations, forming the first top interconnect structure 218 includes forming the first top interconnect structure 218 in the first recess 302 such that the first top interconnect structure lands on a metallization layer (e.g., a conductive structure 214) that is exposed in the first recess 302.

In a fifth implementation, alone or in combination with one or more of the first through fourth implementations, forming the second top interconnect structure 218 includes forming the second top interconnect structure 218 in the second recess 304 such that the second top interconnect structure 218 lands on a third dielectric layer (e.g., another backend dielectric layer 210) under the first dielectric layer (e.g., the backend dielectric layer 210).

Although FIG. 8 shows example blocks of process 800, in some implementations, process 800 includes additional blocks, fewer blocks, different blocks, or differently arranged blocks than those depicted in FIG. 8. Additionally, or alternatively, two or more of the blocks of process 800 may be performed in parallel.

In this way, a semiconductor die includes top conductive structures of different sizes, and bonding vias and associated bonding pads are formed only on the larger top conductive structures. Forming the bonding vias on the larger top conductive structures results in lesser vertical dimensions (e.g., lesser lengths) for the bonding vias of the semiconductor die, which reduces the amount of narrowing that occurs in the width of the bonding vias. In particular, the larger top conductive structures in the semiconductor die may be taller than the smaller top conductive structures in the semiconductor die, and therefore the vertical distance that the bonding vias span in the semiconductor die is reduced, which reduces the amount of narrowing that occurs in the width of the bonding vias. This results in a greater amount of surface area contact between the bottom of the bonding vias and the underlying top conductive structures (e.g., the larger top conductive structures), which enables a low contact resistance to be achieved between the bonding vias and the underlying top conductive structures.

As described in greater detail above, some implementations described herein provide a semiconductor die. The semiconductor die includes a backend dielectric layer. The semiconductor die includes a bonding dielectric layer above the backend dielectric layer. The semiconductor die includes a metallization layer, in the backend dielectric layer, that includes a first top conductive structure having a first width and a second top conductive structure having a second width that is greater than the first width. An entirety of a first top surface of the first top conductive structure is in physical contact with the backend dielectric layer. The semiconductor die includes a bonding via in physical contact with a second top surface of the second top conductive structure. The semiconductor die includes a bonding pad in physical contact with the bonding via.

As described in greater detail above, some implementations described herein provide a stacked semiconductor device. The stacked semiconductor device includes a first semiconductor die. The first semiconductor die includes a first backend dielectric layer, a first bonding dielectric layer above the first backend dielectric layer, and a first metallization layer in the first backend dielectric layer. The first metallization layer includes a first top conductive structure having a first width and a second top conductive structure having a second width that is greater than the first width. An entirety of a first top surface of the first top conductive structure is in physical contact with the first backend dielectric layer. The first semiconductor die includes a first bonding via in physical contact with a second top surface of the second top conductive structure, and a first bonding pad in physical contact with the bonding via. The stacked semiconductor device includes a second semiconductor die bonded with the first semiconductor die such that the first semiconductor die and the second semiconductor die are vertically arranged in the stacked semiconductor device. The second semiconductor die includes a second backend dielectric layer, a second bonding dielectric layer below the second backend dielectric layer, and a second metallization layer in the second backend dielectric layer. The second metallization layer includes a third top conductive structure. The second semiconductor die includes a second bonding via in physical contact with a third top surface of the third top conductive structure, and a second bonding pad in physical contact with the second bonding via, where the first bonding pad of the first semiconductor die and the second bonding pad of the second semiconductor die are bonded in a metal-to-metal bond, and where the first bonding dielectric layer of the first semiconductor die and the second bonding dielectric layer of the second semiconductor die are bonded in a dielectric-to-dielectric bond.

As described in greater detail above, some implementations described herein provide a method. The method includes forming a first recess and a second recess in a first dielectric layer above a substrate of a semiconductor die. The method includes forming a patterned masking layer above the first dielectric layer such that the first recess and the second recess are exposed through the patterned masking layer, where a first width of a first opening in the patterned masking layer above the first recess is less than a second width of a second opening in the patterned masking layer above the second recess. The method includes forming, through the first opening in the patterned masking layer, a first top interconnect structure in the first recess and a first top conductive structure on the first top interconnect structure. The method includes forming, through the second opening in the patterned masking layer, a second top interconnect structure in the second recess and a second top conductive structure on the second top interconnect structure. The method includes forming a second dielectric layer on the first dielectric layer such that the second dielectric layer encapsulates the first top conductive structure and the second top conductive structure. The method includes forming a third recess through the second dielectric layer to the second top conductive structure. The method includes forming, while the first top conductive structure remains encapsulated by the second dielectric layer, a bonding via on the second top conductive structure in the third recess in the second dielectric layer. The method includes forming, while the first top conductive structure remains encapsulated by the second dielectric layer, a bonding pad on the bonding via.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor die, comprising:
a backend dielectric layer;
a bonding dielectric layer above the backend dielectric layer;
a metallization layer, in the backend dielectric layer, comprising:
a first top conductive structure having a first width,
wherein an entirety of a first top surface of the first top conductive structure is in physical contact with the backend dielectric layer; and
a second top conductive structure having a second width that is greater than the first width;
a bonding via in physical contact with a second top surface of the second top conductive structure; and
a bonding pad in physical contact with the bonding via.

2. The semiconductor die of claim 1, wherein a ratio of the second width to the first width is included in a range of approximately 2.5:1 to approximately 10.66:1.

3. The semiconductor die of claim 1, wherein a first thickness of the first top conductive structure is less than a second thickness of the second top conductive structure.

4. The semiconductor die of claim 1, further comprising:
a first top interconnect structure below and coupled with the first top conductive structure;
a second top interconnect structure below and coupled with the second top conductive structure; and
a plurality of third top conductive structures below and coupled with the first top interconnect structure and with an integrated circuit device in a device layer of the semiconductor die.

5. The semiconductor die of claim 4, further comprising:
a plurality of fourth top conductive structures below and coupled with the second top interconnect structure,
wherein one or more of the fourth top conductive structures are coupled with one or more of the third top conductive structures.

6. The semiconductor die of claim 4, further comprising:
a plurality of fourth top conductive structures below and coupled with the second top interconnect structure and with another integrated circuit device in the device layer of the semiconductor die.

7. The semiconductor die of claim 1, wherein the metallization layer further comprises:
a connecting structure that connects the first top conductive structure and the second top conductive structure.

8. A stacked semiconductor device, comprising:
a first semiconductor die, comprising:
a first backend dielectric layer;
a first bonding dielectric layer above the first backend dielectric layer;
a first metallization layer, in the first backend dielectric layer, comprising:
a first top conductive structure having a first width,
wherein an entirety of a first top surface of the first top conductive structure is in physical contact with the first backend dielectric layer; and
a second top conductive structure having a second width that is greater than the first width;
a first bonding via in physical contact with a second top surface of the second top conductive structure; and
a first bonding pad in physical contact with the bonding via; and
a second semiconductor die, bonded with the first semiconductor die such that the first semiconductor die and the second semiconductor die are vertically arranged in the stacked semiconductor device, comprising:
a second backend dielectric layer;
a second bonding dielectric layer below the second backend dielectric layer;
a second metallization layer, in the second backend dielectric layer, comprising a third top conductive structure;
a second bonding via in physical contact with a third top surface of the third top conductive structure; and
a second bonding pad in physical contact with the second bonding via,
wherein the first bonding pad of the first semiconductor die and the second bonding pad of the second semiconductor die are bonded in a metal-to-metal bond, and
wherein the first bonding dielectric layer of the first semiconductor die and the second bonding dielectric layer of the second semiconductor die are bonded in a dielectric-to-dielectric bond.

9. The stacked semiconductor device of claim 8, wherein the second semiconductor die further comprises a fourth top conductive structure;
wherein the third top conductive structure has a third width; and
wherein the fourth top conductive structure has a fourth width that is less than the third width.

10. The stacked semiconductor device of claim 9, wherein portions of each of the first backend dielectric layer, the second backend dielectric layer, the first bonding dielectric layer, and the second bonding dielectric layer are directly between the first top conductive structure and the fourth top conductive structure; and
wherein the first bonding via, the second bonding via, the first bonding pad, and the second bonding pad are directly between the second top conductive structure and the third top conductive structure.

11. The stacked semiconductor device of claim 9, wherein an entirety of a fourth top surface of the fourth top conductive structure is in physical contact with the second backend dielectric layer.

12. The stacked semiconductor device of claim 9, wherein the second semiconductor die further comprises:
a third bonding via in physical contact with a fourth top surface of the fourth top conductive structure; and
a third bonding pad in physical contact with the third bonding via.

13. The stacked semiconductor device of claim 12, wherein portions of each of the first backend dielectric layer and the first bonding dielectric layer are directly between the first top conductive structure and the third bonding pad.

14. The stacked semiconductor device of claim 8, wherein the second top surface of the second top conductive structure is located closer to the second bonding dielectric layer than the first top surface of the first top conductive structure.

15. A method, comprising:
forming a first recess and a second recess in a first dielectric layer above a substrate of a semiconductor die;
forming a patterned masking layer above the first dielectric layer such that the first recess and the second recess are exposed through the patterned masking layer,
wherein a first width of a first opening in the patterned masking layer above the first recess is less than a second width of a second opening in the patterned masking layer above the second recess;
forming, through the first opening in the patterned masking layer, a first top interconnect structure in the first recess and a first top conductive structure on the first top interconnect structure;
forming, through the second opening in the patterned masking layer, a second top interconnect structure in the second recess and a second top conductive structure on the second top interconnect structure;
forming a second dielectric layer on the first dielectric layer such that the second dielectric layer encapsulates the first top conductive structure and the second top conductive structure;
forming a third recess through the second dielectric layer to the second top conductive structure;
forming, while the first top conductive structure remains encapsulated by the second dielectric layer, a bonding via on the second top conductive structure in the third recess in the second dielectric layer; and
forming, while the first top conductive structure remains encapsulated by the second dielectric layer, a bonding pad on the bonding via.

16. The method of claim 15, further comprising:
forming a bonding dielectric layer on the second dielectric layer; and
forming a fourth recess in the bonding dielectric layer,
wherein forming the bonding pad comprises:
forming the bonding pad on the bonding via in the fourth recess in the bonding dielectric layer.

17. The method of claim 15, wherein forming the first top conductive structure comprises:
forming the first top conductive structure to a first height; and
wherein forming the second top conductive structure comprises:
forming the second top conductive structure to a second height that is greater than the first height.

18. The method of claim 15, further comprising:
removing the patterned masking layer after forming the first top interconnect structure, the second top interconnect structure, the first top conductive structure, and the second top conductive structure; and
wherein forming the second dielectric layer comprises:
forming the second dielectric layer in areas of the semiconductor die that were previously occupied by the patterned masking layer.

19. The method of claim 15, wherein forming the first top interconnect structure comprises:
forming the first top interconnect structure in the first recess such that the first top interconnect structure lands on a metallization layer that is exposed in the first recess.

20. The method of claim 19, wherein forming the second top interconnect structure comprises:
forming the second top interconnect structure in the second recess such that the second top interconnect structure lands on a third dielectric layer under the first dielectric layer.
